(19) United States
(12) Patent Application Publication
(10) Pub. No.: US 2026/0362713 A1
(43) Pub. Date: Nov. 12, 2026

(54) HIGH BANDWIDTH HYBRID 3D MEMORY DEVICE

(71) Applicant: Yangtze Memory Technologies Holding Co., Ltd., Wuhan (CN)

(72) Inventors: Zongliang HUO, Wuhan (CN); Zhiliang XIA, Wuhan (CN)

(21) Appl. No.: 19/389,784

(22) Filed: Nov. 14, 2025

Related U.S. Application Data
(63) Continuation of application No. PCT/CN2025/093476, filed on May 8, 2025.

(51) Int. Cl. H10B 80/00; H10W 90/00; H10W 90/20

(52) U.S. Cl. CPC H10B 80/00; H10W 90/00; H10W 90/297; H10W 90/722; H10W 90/724

(57) ABSTRACT

Methods, devices, systems, and techniques for managing vertically stacked memory devices in 3D semiconductor devices are provided. In one aspect, a semiconductor device includes a first deck of volatile memory devices including at least a first volatile memory device and a second volatile memory device stacked along a first direction and bonded through a first bonding layer having conductive bonding contacts that are coupled to first connection structures and second connection structures. The semiconductor device also includes a second deck of non-volatile memory devices stacked on the first deck. The second deck includes at least a first non-volatile memory device and a second non-volatile memory device stacked along the first direction and bonded through first conductive bumps. The first conductive bumps are coupled to the second non-volatile memory device and second connection structures. The semiconductor device also includes a logic device coupled to the first deck and the second deck.

### CROSS-REFERENCE TO RELATED APPLICATIONS

This application is a continuation of International Application No. PCT/CN2025/093476, filed on May 08, 2025, the disclosure of which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a stack of memory arrays and peripheral circuits for facilitating operations of the memory array. The memory arrays can be stacked on top of each other and can be connected by various bonding contacts.

### SUMMARY

The present disclosure describes methods, devices, systems and techniques for managing vertically stacked memory devices in three-dimensional (3D) semiconductor devices.

One aspect of the present disclosure features a semiconductor device. The semiconductor device includes a first deck of volatile memory devices including at least a first volatile memory device and a second volatile memory device stacked along a first direction and bonded through a first bonding layer in between, where the first bonding layer includes conductive bonding contacts and a dielectric material isolating the conductive bonding contacts, and the conductive bonding contacts in the first bonding layer are coupled to first connection structures extending along the first direction in the first volatile memory device and second connection structures extending along the first direction in the second volatile memory device; a second deck of non-volatile memory devices stacked on the first deck along the first direction, where the second deck includes at least a first non-volatile memory device and a second non-volatile memory device stacked along the first direction and bonded through first conductive bumps in between, and the first conductive bumps are coupled to fourth connection structures in the second non-volatile memory device and third connection structures in the first non-volatile memory device; and a logic device coupled to the first deck and the second deck.

In some implementations, the first volatile memory device includes a dynamic random access memory (DRAM) device, and the first non-volatile memory device includes a NAND flash memory device.

In some implementations, the DRAM device includes a first semiconductor structure including an array of DRAM cells and a second semiconductor structure including a peripheral circuit configured to control the array of DRAM cells, and the first semiconductor structure and the second semiconductor structure are stacked along the first direction.

In some implementations, the first semiconductor structure and the second semiconductor structure are bonded through a second bonding layer in between including conductive bonding contacts and a dielectric material isolating the conductive bonding contacts.

In some implementations, the NAND flash memory device includes a first semiconductor structure including an array of NAND flash memory cells and a second semiconductor structure including a peripheral circuit configured to control the array of NAND flash memory cells, and the first semiconductor structure and the second semiconductor structure are stacked along the first direction.

In some implementations, the first semiconductor structure and the second semiconductor structure are bonded through a third bonding layer in between including conductive bonding contacts and a dielectric material isolating the conductive bonding contacts.

In some implementations, the semiconductor device further includes an interposer, where the first deck, the second deck, the logic device, and the interposer are stacked along the first direction, and the logic device is between the first deck and the interposer along the first direction.

In some implementations, the semiconductor device further includes an interposer, where the first deck and the logic device are integrated on different positions of the interposer along a second direction perpendicular to the first direction.

In some implementations, the first deck and the second deck are coupled through second conductive bumps in between, and the second conductive bumps are isolated by an insulation material.

In some implementations, the logic device includes a control circuit module, and the control circuit module includes an access frequency judgement unit configured to determine an access frequency of a data unit stored in the first deck or the second deck.

In some implementations, the access frequency judgement unit includes a counter circuit, a timer circuit, a comparator circuit, and an auxiliary circuit.

In some implementations, a pitch of the first connection structures in the first volatile memory device is smaller than a pitch of the third connection structures in the first non-volatile memory device.

In some implementations, the semiconductor device has a first device area, a second device area, and a connection area between the first device area and the second device area along a second direction perpendicular to the first direction, and the first connection structures in the first volatile memory device include input/output (I/O) connection structures in the connection area and power connection structures in the first device area, the second device area, and the connection area, the I/O connection structures are configured to provide data path signals to the first volatile memory device, and the power connection structures are configured to provide power supplies to the first volatile memory device.

In some implementations, the second deck includes at least 256 input/output (I/O) pins, the second deck includes four non-volatile memory devices, one of the four non-volatile memory devices includes eight channels, and one of the eight channels includes at least six planes and eight I/O pins.

In some implementations, at least one volatile memory device of the first deck of volatile memory devices is configured to store hot data with a relatively higher access frequency, and at least one non-volatile memory device of the second deck of non-volatile memory devices is configured to store warm or cold data with a relatively lower access frequency.

Another aspect of the present disclosure features a method of forming a semiconductor device. The method includes forming a first deck of semiconductor structures including at least a first semiconductor structure and a second semiconductor structure stacked along a first direction and bonded through a first bonding layer in between, where the first semiconductor structure includes at least one volatile memory device, the first bonding layer includes conductive bonding contacts and a dielectric material isolating the conductive bonding contacts, and the conductive bonding contacts in the first bonding layer are coupled to first connection structures extending along the first direction in the first semiconductor structure and second connection structures extending along the first direction in the second semiconductor structure; forming a second deck of semiconductor structures including at least a third semiconductor structure and a fourth semiconductor structure stacked along the first direction and bonded through first conductive bumps in between, where the third semiconductor structure includes at least one non-volatile memory device, and the first conductive bumps are coupled to the fourth semiconductor structure and third connection structures extending along the first direction in the third semiconductor structure; bonding the first deck to the second deck, where the first deck and the second deck are stacked along the first direction; and forming a fifth semiconductor structure coupled to the first deck and the second deck, where the fifth semiconductor structure includes at least one logic device.

In some implementations, forming the first deck includes: forming the first semiconductor structure; forming the first connection structures in the first semiconductor structure; forming the second semiconductor structure; forming the second connection structures in the second semiconductor structure; forming a first sub-bonding layer on top of the first semiconductor structure, where the first sub-bonding layer includes conductive bonding contacts and a dielectric material isolating the conductive bonding contacts; forming a second sub-bonding layer on bottom of the second semiconductor structure, where the second sub-bonding layer includes conductive bonding contacts and a dielectric material isolating the conductive bonding contacts, and the conductive bonding contacts in the first sub-bonding layer are configured to align with the conductive bonding contacts in the second sub-bonding layer along the first direction; and bonding the first semiconductor structure to the second semiconductor structure by bonding the conductive bonding contacts in the first sub-bonding layer to the conductive bonding contacts in the second sub-bonding layer and the dielectric material in the first sub-bonding layer to the dielectric material in the second sub-bonding layer.

In some implementations, forming the second deck includes: forming the third semiconductor structure; forming the third connection structures in the third semiconductor structure; forming the fourth semiconductor structure; forming conductive bonding contacts on top of the third semiconductor structure; forming the first conductive bumps on bottom of the fourth semiconductor structure, where the conductive bonding contacts on top of the third semiconductor structure are configured to align with the first conductive bumps on bottom of the fourth semiconductor structure; and bonding the third semiconductor structure to the fourth semiconductor structure by bonding the conductive bonding contacts on top of the third semiconductor structure to the first conductive bumps on bottom of the fourth semiconductor structure.

In some implementations, bonding the first deck to the second deck includes: forming conductive bonding contacts on top of the first deck; forming conductive bumps on bottom of the second deck, where the conductive bonding contacts on top of the first deck are configured to align with the conductive bumps on bottom of the second deck; and bonding the conductive bonding contacts on top of the first deck to the conductive bumps on bottom of the second deck.

In some implementations, the method further includes bonding the first deck to the fifth semiconductor structure, where the first deck and the fifth semiconductor structure are stacked along the first direction; and bonding the fifth semiconductor structure to an interposer, where the second deck, the first deck, the fifth semiconductor structure, and the interposer are stacked along the first direction.

In some implementations, the method further includes bonding the first deck to an interposer, where the second deck, the first deck, and the interposer are stacked along the first direction; and bonding the fifth semiconductor structure to the interposer, where the fifth semiconductor structure and the interposer are stacked along the first direction, and the first deck and the fifth semiconductor structure are integrated on different positions of the interposer along a second direction perpendicular to the first direction.

Another aspect of the present disclosure features a semiconductor device. The semiconductor device includes a first deck of volatile memory devices including at least a first volatile memory device and a second volatile memory device stacked along a first direction and bonded through a first bonding layer in between, where the first bonding layer includes a dielectric material and excludes a conductive bonding contact, the first deck further includes first connection structures, a first contact structure, and a second contact structure extending along the first direction, the first connection structures extend through the first bonding layer, the first contact structure extends through the first bonding layer and is coupled to the second volatile memory device, and the second contact structure extends into and is coupled to the first volatile memory device without extending through the first bonding layer; a second deck of non-volatile memory devices stacked on the first deck along the first direction, where the second deck includes at least a first non-volatile memory device and a second non-volatile memory device stacked along the first direction and bonded through a second bonding layer in between, the second bonding layer includes conductive bonding contacts and a dielectric material isolating the conductive bonding contacts, the conductive bonding contacts in the second bonding layer are coupled to the second non-volatile memory device and second connection structures extending along the first direction in the first non-volatile memory device, and the second connection structures in the first non-volatile memory device are coupled to the first connection structures in the first deck; and a logic device coupled to the first deck and the second deck.

In some implementations, the first volatile memory device includes a dynamic random access memory (DRAM) device, and the first non-volatile memory device includes a NAND flash memory device.

In some implementations, the DRAM device includes a first semiconductor structure including an array of DRAM cells and a second semiconductor structure including a peripheral circuit configured to control the array of DRAM cells, and the first semiconductor structure and the second semiconductor structure are stacked along the first direction.

In some implementations, the first semiconductor structure and the second semiconductor structure are bonded through a third bonding layer in between including conductive bonding contacts and a dielectric material isolating the conductive bonding contacts.

In some implementations, the NAND flash memory device includes a first semiconductor structure including an array of NAND flash memory cells and a second semiconductor structure including a peripheral circuit configured to control the array of NAND flash memory cells, and the first semiconductor structure and the second semiconductor structure are stacked along the first direction.

In some implementations, the first semiconductor structure and the second semiconductor structure are bonded through a fourth bonding layer in between including conductive bonding contacts and a dielectric material isolating the conductive bonding contacts.

In some implementations, the semiconductor device further includes an interposer, where the first deck, the second deck, the logic device, and the interposer are stacked along the first direction, and the logic device is between the first deck and the interposer along the first direction.

In some implementations, the semiconductor device further includes an interposer, where the first deck and the logic device are integrated on different positions of the interposer along a second direction perpendicular to the first direction.

In some implementations, the first deck and the second deck are coupled through a fifth bonding layer in between including conductive bonding contacts and a dielectric material isolating the conductive bonding contacts.

In some implementations, the logic device includes a control circuit module, and the control circuit module includes an access frequency judgement unit configured to determine an access frequency of a data unit stored in the first deck or the second deck.

In some implementations, the access frequency judgement unit includes a counter circuit, a timer circuit, a comparator circuit, and an auxiliary circuit.

In some implementations, a pitch of the first connection structures, the first contact structure, and the second contact structure is equal to or smaller than a pitch of the second connection structures in the first non-volatile memory device.

In some implementations, the semiconductor device has a first device area, a second device area, and a connection area between the first device area and the second device area along a second direction perpendicular to the first direction, and the second connection structures in the first non-volatile memory device include input/output (I/O) connection structures in the connection area and power connection structures in the first device area, the second device area, and the connection area, the I/O connection structures are configured to provide data path signals to the first volatile memory device, and the power connection structures are configured to provide power supplies to the first volatile memory device.

In some implementations, the second deck includes at least 256 input/output (I/O) pins, the second deck includes four non-volatile memory devices, one of the four non-volatile memory devices includes eight channels, and one of the eight channels includes at least six planes and eight I/O pins.

In some implementations, at least one volatile memory device of the first deck of volatile memory devices is configured to store hot data with a relatively higher access frequency, and at least one non-volatile memory device of the second deck of non-volatile memory devices is configured to store warm or cold data with a relatively lower access frequency.

A further aspect of the present disclosure features a method of forming a semiconductor device. The method includes forming a first deck of semiconductor structures including at least a first semiconductor structure and a second semiconductor structure stacked along a first direction and bonded through a first bonding layer in between, where the first semiconductor structure includes at least one volatile memory device, and the first bonding layer includes a dielectric material and excludes a conductive bonding contact, the first deck further includes first connection structures, a first contact structure, and a second contact structure extending along the first direction, the first connection structures extend through the first bonding layer, the first contact structure extends through the second bonding layer and is coupled to the second semiconductor structure, and the second contact structure extends into and is coupled to the first semiconductor structure; forming a second deck of semiconductor structures including at least a third semiconductor structure and a fourth semiconductor structure stacked along the first direction and bonded through a second bonding layer in between, where the third semiconductor structure includes at least one non-volatile memory device, and the second bonding layer includes conductive bonding contacts and a dielectric material isolating the conductive bonding contacts, and the conductive bonding contacts in the second bonding layer are coupled to the fourth semiconductor structure and second connection structures extending along the first direction in the third semiconductor structure; bonding the first deck to the second deck, where the first deck and the second deck are stacked along the first direction, and the second connection structures in the third semiconductor structure are coupled to the first connection structures in the first deck; and forming a fifth semiconductor structure coupled to the first deck and the second deck, where the fifth semiconductor structure includes at least one logic device.

In some implementations, forming the first deck includes: forming the first semiconductor structure; forming the second semiconductor structure; forming a first dielectric layer on top of the first semiconductor structure; forming a second dielectric layer on bottom of the second semiconductor structure; and bonding the first semiconductor structure to the second semiconductor structure by bonding the first dielectric layer to the second dielectric layer, where the first bonding layer includes the first dielectric layer and the second dielectric layer.

In some implementations, forming the first deck further includes: forming the first connection structures extending through the first semiconductor structure, the first bonding layer, and the second semiconductor structure; forming the first contact structure extending through the first semiconductor structure and the first bonding layer and into the second semiconductor structure; forming the second contact structure extending into the first semiconductor structure without extending through the first bonding layer; and forming an interconnect layer on top of the first deck, where the interconnect layer is coupled to the first connection structures.

In some implementations, forming the second deck includes: forming the third semiconductor structure; forming the second connection structures in the third semiconductor structure; forming the fourth semiconductor structure; forming a first sub-bonding layer on top of the third semiconductor structure, where the first sub-bonding layer includes conductive bonding contacts and a dielectric material isolating the conductive bonding contacts; forming a second sub-bonding layer on bottom of the fourth semiconductor structure, where the second sub-bonding layer includes conductive bonding contacts and a dielectric material isolating the conductive bonding contacts, and the conductive bonding contacts in the first sub-bonding layer are configured to align with the conductive bonding contacts in the second sub-bonding layer along the first direction; and bonding the third semiconductor structure to the fourth semiconductor structure by bonding the conductive bonding contacts in the first sub-bonding layer to the conductive bonding contacts in the second sub-bonding layer and the dielectric material in the first sub-bonding layer to the dielectric material in the second sub-bonding layer.

In some implementations, bonding the first deck to the second deck includes: forming a third sub-bonding layer on top of the first deck, where the third sub-bonding layer includes conductive bonding contacts and a dielectric material isolating the conductive bonding contacts, and the conductive bonding contacts in the third sub-bonding layer are coupled to an interconnect layer of the first deck; forming a fourth sub-bonding layer on bottom of the second deck, where the fourth sub-bonding layer includes conductive bonding contacts and a dielectric material isolating the conductive bonding contacts, the conductive bonding contacts in the fourth sub-bonding layer are configured to align with the conductive bonding contacts in the third sub-bonding layer along the first direction, and the conductive bonding contacts in the fourth sub-bonding layer are coupled to the second connection structures in the third semiconductor structure; and bonding the first deck to the second deck by bonding the conductive bonding contacts in the third sub-bonding layer to the conductive bonding contacts in the fourth sub-bonding layer and the dielectric material in the third sub-bonding layer to the dielectric material in the fourth sub-bonding layer.

In some implementations, the method further includes bonding the first deck to the fifth semiconductor structure, where the first deck and fifth semiconductor structure are stacked along the first direction; and bonding the fifth semiconductor structure to an interposer, where the second deck, the first deck, the fifth semiconductor structure, and the interposer are stacked along the first direction.

In some implementations, the method further includes bonding the first deck to an interposer, where the second deck, the first deck, and the interposer are stacked along the first direction; and bonding the fifth semiconductor structure to the interposer, where the fifth semiconductor structure and the interposer are stacked along the first direction, and the first deck and the fifth semiconductor structure are integrated on different positions of the interposer along a second direction perpendicular to the first direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIGS. 1A – 1E illustrate cross-sectional views of semiconductor devices.

FIG. 1F illustrates top views of the semiconductor device of FIG. 1A.

FIGS. 2A – 2E illustrate cross-sectional views of semiconductor devices.

FIG. 2F illustrates top views of the semiconductor device of FIG. 2A.

FIGS. 3A – 3C illustrate circuit diagrams of a semiconductor device.

FIG. 4A – 4B illustrate circuit diagrams of a semiconductor device.

FIGS. 5A – 5J show cross-sectional views of structures of a semiconductor device of FIG. 1A at various stages of a fabrication process.

FIGS. 6A – 6I show cross-sectional views of structures of a semiconductor device of FIG. 2A at various stages of a fabrication process.

FIG. 7 illustrate a flow chart of an example process of manufacturing the semiconductor device of FIG. 1A.

FIG. 8 illustrate a flow chart of an example process of manufacturing the semiconductor device of FIG. 2A.

FIG. 9 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the development of artificial intelligence (AI) applications, the amount of data that needs to be stored in memory devices has increased drastically. This data can be categorized based on access frequency. High access frequency data needs to be accessed regularly, requiring high access speed. Low access frequency data generally has a large data size but is accessed less frequently compared to high access frequency data. Currently, data is not being differentiated based on access frequency, and all data is stored using volatile memory devices (e.g., DRAM) to maintain high access speed. The use of only volatile memory devices may pose challenges in storage capacity due to their generally low storage capacity. Additionally, the cost of expanding volatile memory devices may increase fabrication costs and device footprint. Thus, a memory device that can solve the aforementioned problems is desirable.

In one or more implementations of the present disclosure, an example semiconductor device is provided. The semiconductor device includes a first deck of volatile memory devices including at least a first volatile memory device and a second volatile memory device stacked along a first direction and bonded through a first bonding layer in between, where the first bonding layer includes conductive bonding contacts and a dielectric material isolating the conductive bonding contacts, and the conductive bonding contacts in the first bonding layer are coupled to first connection structures extending along the first direction in the first volatile memory device and second connection structures extending along the first direction in the second volatile memory device. The semiconductor device also includes a second deck of non-volatile memory devices stacked on the first deck along the first direction, where the second deck includes at least a first non-volatile memory device and a second non-volatile memory device stacked along the first direction and bonded through first conductive bumps in between, and the first conductive bumps are coupled to the second non-volatile memory device and second connection structures in the first non-volatile memory device; and a logic device coupled to the first deck and the second deck.

Implementations of the present disclosure can provide one or more of the following technical advantages and/or benefits. First, both volatile memory devices and non-volatile memory devices are integrated into the memory device described in the current disclosure. The volatile memory devices and non-volatile memory devices are stacked on top of each other, forming a hybrid 3D memory device. The integration of volatile and non-volatile memory devices can be used to store different types of data based on access frequency. Specifically, the data can be characterized into three categories based on access frequency and size of the data. Hot data have high access frequency with relatively low size; whereas warm data and cold data generally have low access frequency but requires large storage spaces. Additionally, stacking volatile and non-volatile memory devices can help reduce the footprint of the hybrid 3D memory device. In other words, stacking these memory devices can increase memory density within the memory device. Second, a logic device is also integrated into the memory device using either a 3D stacking or a 2.5D stacking method. The logic device can include a control module with a judgment module that is configured to categorize the data into the three categories based on the access frequency of the data and store the data in either volatile or non-volatile memory devices based on the three categories. For example, the hot data can be stored in the volatile memory device for a fast access with a lower storage capacity, and the warm and cold data can be stored in the non-volatile memory device for a high storage space with a relatively low access speed. In other words, the logic device can improve the efficiency of the hybrid 3D memory device. Third, the volatile and non-volatile memory devices in the 3D memory device can be bonded using different bonding mechanisms. These different bonding mechanisms can improve data transfer efficiency between memory devices while maintaining a cost-effective fabrication process.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

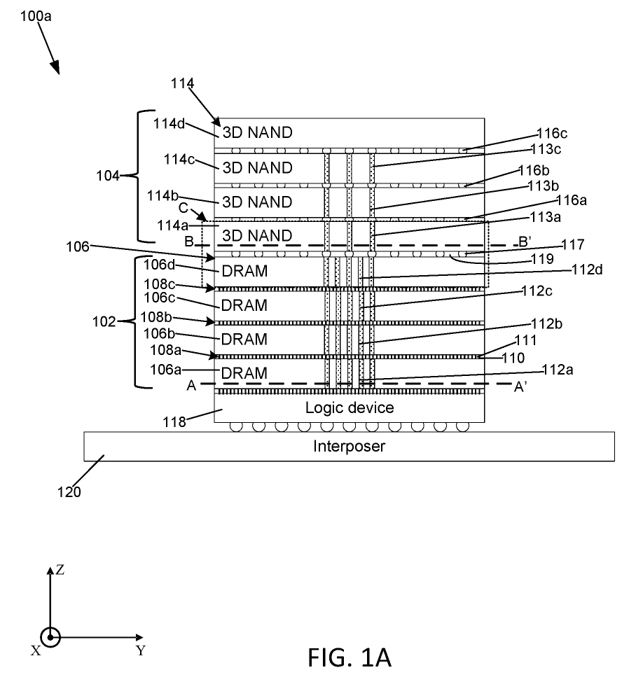

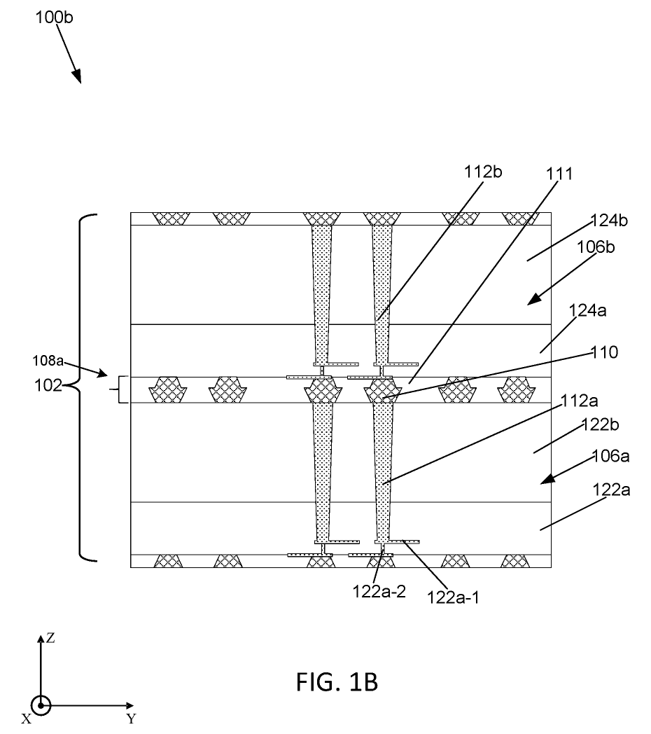

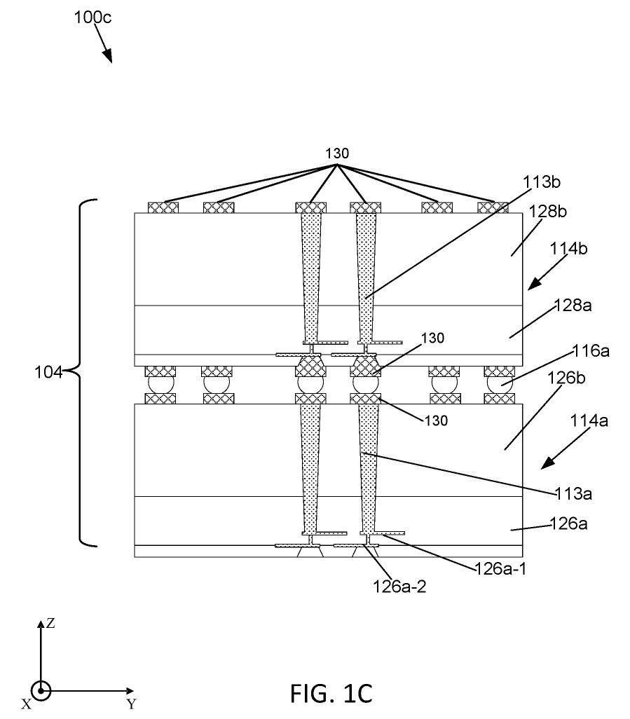

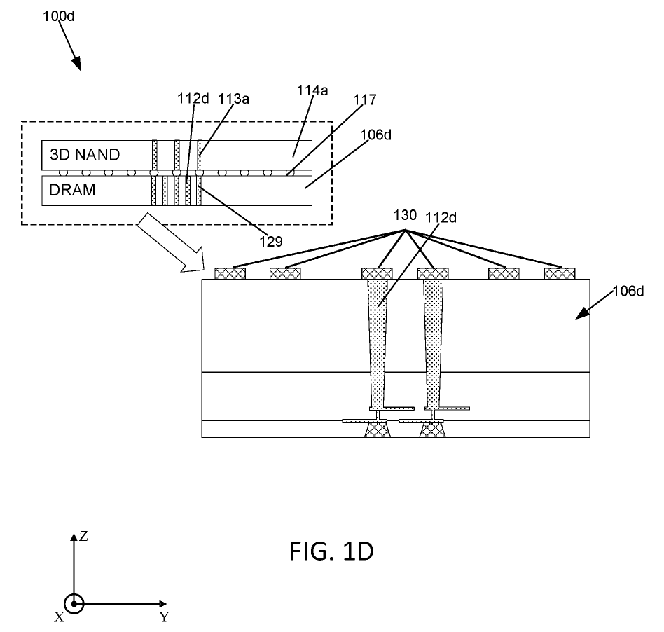

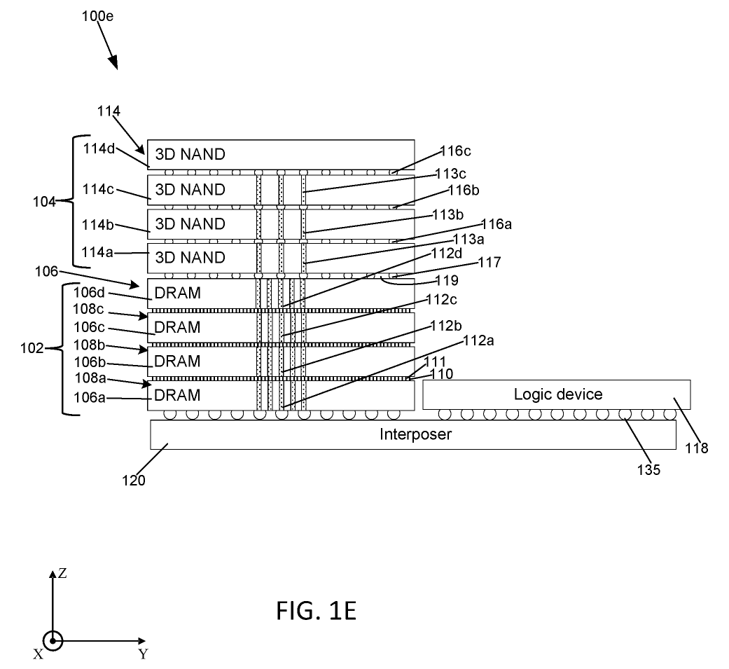

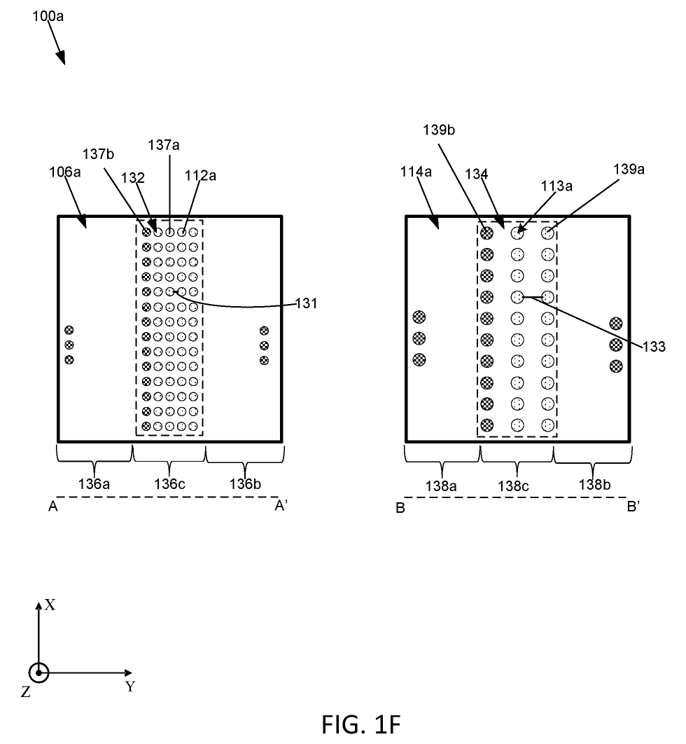

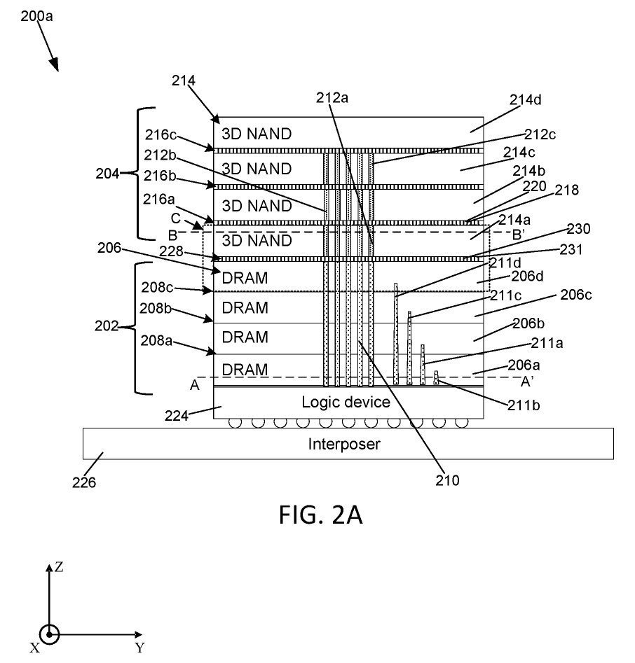

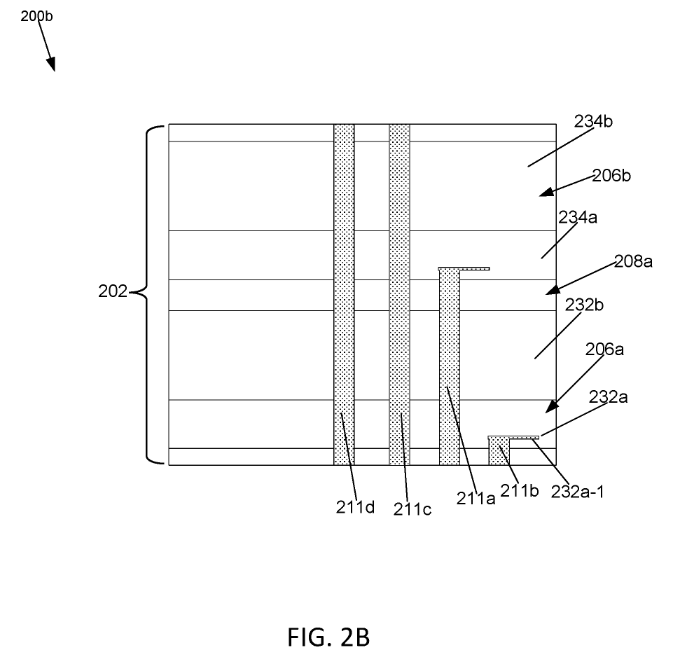

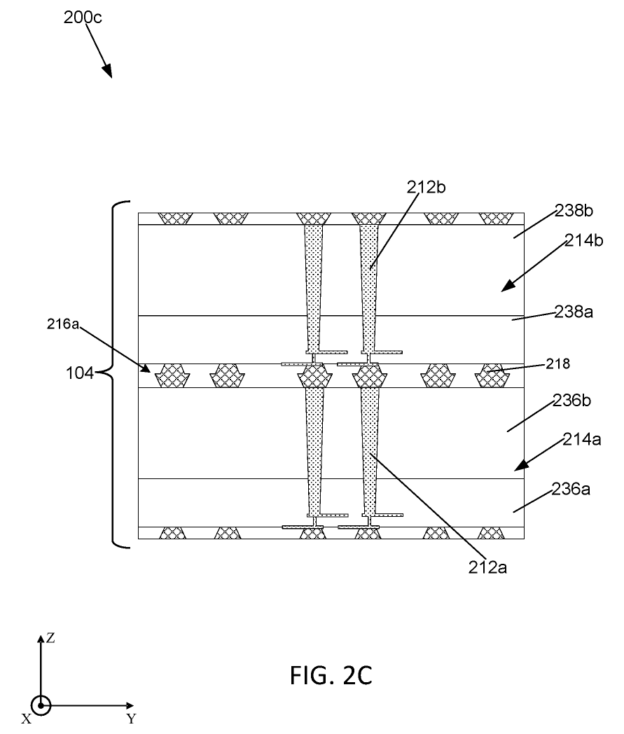

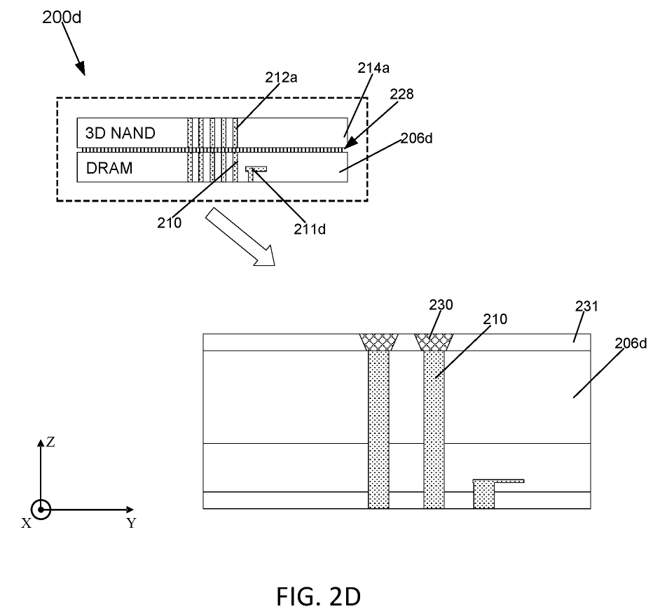

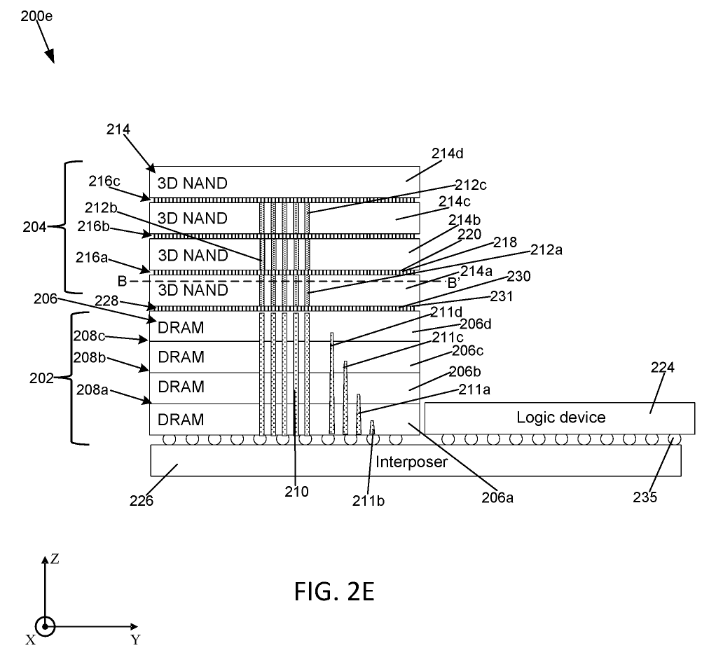

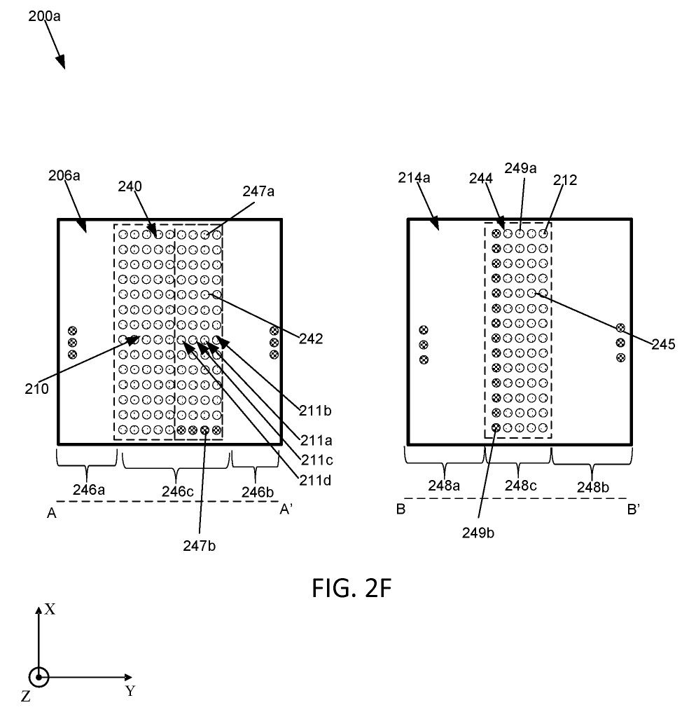

It is noted that X, Y, and Z axes (also referred to as X, Y, and Z directions) are included in FIGS. 1A-1E and FIGS. 2A - 2E to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a cross-sectional view of a 3D semiconductor device 100a. The semiconductor device 100a can include a stack of volatile memory devices such as a 3D dynamic random-access memory (DRAM) and non-volatile memory devices such as a NAND flash memory device. It is understood that FIG. 1A is for illustrative purposes only and may not necessarily reflect the actual device structure (e.g., interconnections) in practice.

As shown in FIG. 1A, the semiconductor device 100a includes a first deck 102 of volatile memory device (e.g., DRAM) and a second deck 104 of non-volatile memory device (e.g., NAND flash memory). The first deck 102 includes a first volatile memory device 106a, a second volatile memory device 106b, a third volatile memory device 106c, and a fourth volatile memory device 106d (collectively referred to as volatile memory devices 106) stacked along a vertical direction (e.g., the Z direction). Adjacent volatile memory devices of the volatile memory devices 106a-106d are bonded through a respective bonding layer. For example, the volatile memory devices 106a and 106b are bonded through a first bonding layer 108a in between. In some implementations, the first bonding layer 108a includes conductive bonding contacts 110 and a dielectric material 111 isolating the conductive bonding contacts 110. The volatile memory devices 106b and 106c are bonded through a second bonding layer 108b in between. The volatile memory devices 106c and 106d are bonded through a third bonding layer 108c in between. In some implementations, the second bonding layer 108b and the third bonding layer 108c can be similar to, or same as the first bonding layer 108a. In some implementations, each of the volatile memory devices 106 of the semiconductor device 100a can include connection structures extending along the Z direction. For example, the first volatile memory device 106a includes connection structures 112a (also referred to as first connection structures), the second volatile memory device 106b includes connection structures 112b (also referred to as second connection structures), the third volatile memory device 106c includes connection structures 112c, and the fourth volatile memory device 106d includes connection structures 112d. In some implementations, the connection structures 112a are coupled to the conductive bonding contacts 110 in the first bonding layer 108a, the connection structures 112b are coupled to corresponding conductive bonding contacts in the first bonding layer 108a and the second bonding layer 108b, the connection structures 112c are coupled to corresponding conductive bonding contacts in the second bonding layer 108b and the third bonding layer 108c, and the connection structures 112d are coupled to corresponding conductive bonding contacts in the third bonding layer 108c along the Z direction. In some implementations, each of the volatile memory devices 106a-106d can include a first semiconductor structure including an array of DRAM cells and a second semiconductor structure including a peripheral circuit configured to control the array of DRAM cells. In some implementations, the first semiconductor structure and the second semiconductor structure are stacked along the Z direction and are bonded through a second bonding layer in between. In some implementations, the second bonding layer includes conductive bonding contacts similar to the conductive bonding contacts 110 and a dielectric material isolating the conductive bonding contacts.

It is understood that FIG. 1A is for illustration propose only. While the first deck 102 in FIG. 1A includes four volatile memory devices 106a-106d, in practice, the first deck 102 can include any number of volatile memory devices similar to each of the volatile memory devices 106a-106d.

The second deck 104 is stacked on the first deck 102 along the Z direction. In some implementations, as shown in FIG. 1A, the second deck 104 includes a first non-volatile memory device 114a, a second non-volatile memory device 114b, a third non-volatile memory device 114c, and a fourth non-volatile memory device 114d. The non-volatile memory devices 114a-114d (collectively referred to as non-volatile memory devices 114) are stacked along the vertical direction. Adjacent non-volatile memory devices of the non-volatile memory devices 114a-114d are bonded through respective conductive bumps in between. In some implementations, the conductive bumps are isolated by an insulation material. In some implementations, the insulation material can be formed using a non-conductive film (NCF) or using a liquid underfill material and a thermal curing process. For example, the second non-volatile memory device 114b is stacked on the first non-volatile memory device 114a along the Z direction and bonded through conductive bumps 116a in between. The third non-volatile memory device 114c is stacked on the second non-volatile memory device 114b along the Z direction and bonded through conductive bumps 116b in between. The fourth non-volatile memory device 114d is stacked on the third non-volatile memory device 114c along the Z direction and bonded through conductive bumps 116c in between. Each of the non-volatile memory devices 114a-114d of the semiconductor device 100a can include connection structures extending along the Z direction. For example, the first non-volatile memory device 114a includes connection structures 113a (also referred to as third connection structures), the second non-volatile memory device 114b includes connection structures 113b, and the third non-volatile memory device 114c includes connection structures 113c. In some implementations, the conductive bumps 116a – 116c can be microbumps. In some implementations, the connection structures 113a extend through the first non-volatile memory device 114a and are coupled to the conductive bumps 116a along the Z direction, the connection structures 113b extend through the second non-volatile memory device 114b and are coupled to the conductive bumps 116a and 116b along the Z direction, and the connection structures 113c extend through the third non-volatile memory device 114c and are coupled to the conductive bumps 116b and 116c along the Z direction.

In some implementations, the conductive bumps 116a are coupled to the connection structures 113b in the second non-volatile memory device 114b, and the connection structures 113a extending along the Z direction in the first non-volatile memory device 114a.

In some implementations, as shown in FIG. 1A, the first deck 102 and the second deck 104 are coupled through conductive bumps 117 along the Z direction (also referred to as second conductive bumps). The conductive bumps 117 are isolated by an insulation material 119. In some implementations, the insulation material 119 can be formed using a non-conductive film (NCF) or using a liquid underfill material and a thermal curing process. In some implementations, the connection structures 113a are coupled to the conductive bumps 117 along the Z direction. In some implementations, the conductive bumps electrical coupled the connection structures 113a in the first non-volatile memory device 114a and the connection structures 112d in the fourth volatile memory device 106d together along the Z direction.

In some implementations, each of the non-volatile memory devices 114a – 114d can include a first semiconductor structure including an array of NAND flash memory cells and a second semiconductor structure including a peripheral circuit configured to control the array of NAND flash memory cells. In some implementations, the first semiconductor structure and the second semiconductor structure are stacked along the Z direction and are bonded through a third bonding layer in between. In some implementations, the third bonding layer includes conductive bonding contacts and a dielectric material isolating the conductive bonding contacts.

It is understood that FIG. 1A is for illustration propose only. While the second deck 104 in FIG. 1A includes four non-volatile memory devices 114a-114d, in practice, the second deck 104 can include any number of volatile memory devices similar to each of the non-volatile memory devices 114a-114d.

In some implementations, the semiconductor device 100a can be used to store different types of data based on access frequency. The data can be categorized into hot data, warm data, and cold data. The hot data have high access frequency with a relatively low data size, which can be stored in the stack 102 of the volatile memory devices 106a – 106d. The volatile memory devices 106a – 106d can provide a high access speed for the hot data with a relatively low storage capacity. The warm data have medium access frequency with medium data size and the cold data have low access frequency with large data size. The warm and cold data can be stored in the stack 104 of non-volatile memory devices 114a – 114b. The non-volatile memory devices 114a – 114b can provide a high storage capacity with a relative low access speed.

As shown in FIG. 1A, the semiconductor device 100a can further include a logic device 118 coupled to the first deck 102 and the second deck 104. In some implementations, the logic device 118 can include logic circuits that are configured to control the first deck 102 of volatile memory devices 106 and the second deck 104 of non-volatile memory devices 114. In some implementations, the logic device 118 includes a control circuit module. The control circuit module includes an access frequency judgment unit configured to determine an access frequency of a data unit stored in the first deck 102 or the second deck 104. In some implementations, the logic device 118 can include buffer circuitry and test logic for the first deck 102 of volatile memory devices 106 and the second deck 104 of non-volatile memory devices 114.

In some implementations, the semiconductor device 100a can be used to store different types of data that are categorized by access frequency. The data can be categorized into hot data, warm data, and cold data. The hot data has high access frequency, which requires high access speed. The warm data and the cold data have relatively low access frequency. For example, the hot data can be stored in the first deck 102 of the volatile memory devices 106a-106d, which enables a high access speed for the hot data. In another example, the warm data and the cold data can be stored in the second deck 104 of the non-volatile memory devices 114a-114d, which provides a high storage capacity with a relative lower access speed compared to the volatile memory device in the first deck 102.

In some implementations, as shown in FIG. 1A, the semiconductor device 100a also includes an interposer 120. In some implementations, the interposer 120 can be a printed circuit board (PCB). In some implementations, as shown in FIG. 1A, the first deck 102, the second deck 104, and the logic device 118 are stacked on top of the interposer 120 along the Z direction. In some implementations, the logic device 118 is between the interposer 120 and the first deck 102 along the Z direction. The interposer 120 can be configured to couple the logic device 118, the first deck 102 of volatile memory devices 106, and the second deck 104 of non-volatile memory devices 114 to a computing device (not shown in FIG. 1A). The computing device can include at least one processor of an electronic device, such as a central processing unit (CPU), a graphics processing unit (GPU), an application-specific integrated circuit (ASIC), or a system-on-chip (SoC), such as an application processor (AP). In some implementations, the computing device can be an electrical device including but not limited to a desktop computer, a laptop computer, a smartphone, a tablet, and any suitable electrical device thereof. The computing device can be configured to send data to and/or receive data from the first deck 102 and/or the second deck 104 through different channels on the volatile memory devices 106a – 106d and non-volatile memory devices 114a – 114d. For example, each of the volatile memory devices 106a – 106d can include 16 channels and each of the channels has a 64 bits port configured to handle the hot data. In another example, the non-volatile memory devices 114a – 114d can include 8 channels and each of the channels has a 16 bits port configured to handle the warm data and the cold data. In some implementations, the computing device is also configured to transmit memory addresses, operation commands, and clock signals to the first deck 102 and/or the second deck 104 through the logic device 118.The interposer 120 can include interconnection lines that are coupled to the logic device 118 and the computing device. The logic device 118 can be configured to provide physical layer communication protocols (e.g., IEEE-1500) between the first deck 102 and/or the second deck 104 and the computing device. The logic device 118 can be configured to transmit data between the first deck 102 and/or the second deck 104 and the computing device based on control commands and addresses from the computing device.

In some implementations, each of the devices 106, 114, 118, and 120 can be a die or multiple dies stacked together. These devices can be manufactured by depositing multiple layers of various materials and etching them onto a semiconductor wafer in intricate patterns defined by a chip design. After the wafer fabrication process is complete, the wafer that includes individual circuits is cut and diced into individual pieces, each of which is a die. Each die can include a fully functional electronic circuit, which can be a microprocessor, memory, sensor, or any other suitable type of integrated circuit. In some embodiments, each die is encapsulated in a protective package, providing physical support, protection from environmental factor, and connections (e.g., through pins or solder balls) to external devices or system. The device described in other implementations of the present disclosure (e.g., as shown in FIGS. 1E, 2A, 2E) can also be a die or multiple dies stacked together.

FIG. 1B illustrates a cross-sectional view of a semiconductor device 100b. The semiconductor device 100b can be a zoomed in view of two adjacent volatile memory devices 106 (e.g., the first volatile memory device 106a and the second volatile memory device 106b) of the first deck 102 of the semiconductor device 100a of FIG. 1A. In some implementations, the first volatile memory device 106a and the second volatile memory device 106b can be bonded by the first bonding layer 108a through conductive bonding contacts 110. In some implementations, the connection structures 112a and the connection structures 112b are electrically coupled together through the conductive bonding contacts 110 along the Z direction.

In some implementations, as shown in FIG. 1B, each of the first volatile memory devices 106a and the second volatile memory device 106b can include a substrate and an interconnect layer stacked along the Z direction. In some implementations, as shown in FIG. 1B, the first volatile memory device 106a includes the interconnect layer 122a and the substrate 122b. The interconnect layer 122a and the substrate 122b are stacked along the Z direction. The connection structures 112a of the first volatile memory device 106a can extend though the substrate 122b and can be coupled to the interconnect layer 122a. The interconnect layer 122a can include interconnects (also referred to herein as “contacts”), including lateral interconnect lines 122a-1 and vertical interconnect access (VIA) contacts 122a-2. The connection structures 112a can be coupled to the interconnects in the interconnect layer 122a. As used herein, the term “interconnects” can broadly include any suitable types of interconnects, such as middle-end-of-line (MEOL) interconnects and back-end-of-line (BEOL) interconnects. The interconnect layer 122a can further include one or more interlayer dielectric (ILD) layers (also known as “intermetal dielectric (IMD) layers”) in which the interconnect lines 122a-1 and VIA contacts 122a-2 can form. That is, the interconnect layer 122a can include interconnect lines 122a-1 and VIA contacts 122a-2 in multiple ILD layers. The interconnect lines 122a-1 and 122a-2 contacts in the interconnect layer 122a can include conductive materials including, but not limited to, tungsten (W), cobalt (Co), copper (Cu), aluminum (Al), silicides, or any combination thereof. The ILD layers in the interconnect layer 122a can include dielectric materials including, but not limited to, silicon oxide, silicon nitride, silicon oxynitride, low dielectric constant (low-k) dielectrics, or any combination thereof. The substrate 122b can be any suitable semiconductor substrate having any suitable semiconductor materials, such as monocrystalline, polycrystalline or single crystalline semiconductors. For example, the substrate 122b can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof.

In some implementations, as shown in FIG. 1B, the second volatile memory device 106b includes the interconnect layer 124a and the substrate 124b. The interconnect layer 124a and the substrate 124b are stacked along the Z direction. The connection structures 112b of the second volatile memory device 106b can extend though the substrate 124b and can be coupled to the interconnect layer 124a and the connection structures 112a along the Z direction. In some implementations, the connection structures 112b can be similar to, or same as the connection structures 112a. In some implementations, the interconnect layer 124a can be similar to, or same as the interconnect layer 122a. In some implementations, the substrate 124b can be similar to, or same as the substrate 122b.

FIG. 1C illustrates a cross-sectional view of a semiconductor device 100c. The semiconductor device 100c can be a zoomed in view of two adjacent non-volatile memory devices 114 (e.g., the first non-volatile memory device 114a and the second non-volatile memory device 114b) of the second deck 104 of the semiconductor device 100a of FIG. 1A. In some implementations, the first non-volatile memory device 114a and the second non-volatile memory device 114b can be bonded together by the conductive bumps 116a. In some implementations, the connection structures 113a and the connection structures 113b are electrically coupled together through the conductive bumps 116a along the Z direction. In some implementations, the conductive bumps 116a are coupled to the connection structures 113a and 113b through respective metal contacts 130. In some implementations, the conductive bumps 116a are encapsulate by an insulation material. The insulation material can include, but not limited to non-conductive film (NCF), epoxy resin, non-conductive adhesive or any suitable material thereof. The insulation material can have various forms including but not limited to solid form, particle form, and liquid form. In some implementations, the encapsulation can be used to provide physical support of the conductive bumps 116a. In some implementations, the insulation material can be used to dissipate heat generated during an operation of the semiconductor device 100a.

In some implementations, as shown in FIG. 1C, each of the first non-volatile memory device 114a and the second non-volatile memory device 114b can include a substrate and an interconnect layer stacked along the Z direction. In some implementations, as shown in FIG. 1C, the first non-volatile memory device 114a includes the interconnect layer 126a and the substrate 126b. The interconnect layer 126a and the substrate 126b are stacked along the Z direction. The connection structures 113a of the first non-volatile memory device 114a can extend though the substrate 126b and can be coupled to the interconnect layer 126a. The interconnect layer 126a can include interconnects (also referred to herein as “contacts”), including lateral interconnect lines 126a-1 and vertical interconnect access (VIA) contacts 126a-2. The connection structures 113a can be coupled to the interconnects in the interconnect layer 126a. As used herein, the term “interconnects” can broadly include any suitable types of interconnects, such as middle-end-of-line (MEOL) interconnects and back-end-of-line (BEOL) interconnects. The interconnect layer 126a can further include one or more interlayer dielectric (ILD) layers (also known as “intermetal dielectric (IMD) layers”) in which the interconnect lines 126a-1 and VIA contacts 126a-2 can form. That is, the interconnect layer 126a can include interconnect lines 126a-1 and VIA contacts 126a-2 in

In some implementations, as shown in FIG. 1C, the second non-volatile memory device 114b includes the interconnect layer 128a and the substrate 128b. The interconnect layer 128a and the substrate 128b are stacked along the Z direction. The connection structures 113b of the second non-volatile memory device 114b can extend though the substrate 128b and can be coupled to the interconnect layer 128a and the connection structures 113a along the Z direction. In some implementations, the connection structures 113b can be similar to, or same as the connection structures 113a. In some implementations, the interconnect layer 128a can be similar to, or same as the interconnect layer 126a. In some implementations, the substrate 128b can be similar to, or same as the substrate 126b.

FIG. 1D illustrates a cross-sectional view of a semiconductor device 100d. The semiconductor device 100d can be a zoomed in view of zone C of the first deck 102 and the second deck 104 of the semiconductor device 100a of FIG. 1A.

As shown in FIG. 1D, the first non-volatile memory device 114a of the second deck 104 is stacked on top of the fourth volatile memory device 106d of the first deck 102. The first non-volatile memory device 114a and the fourth volatile memory device 106d are bonded together through the conductive bumps 117 in between. In some implementations, as shown in FIG. 1D, the fourth volatile memory device 106d includes metal contacts 130. The conductive bumps 117 are in contact with corresponding metal contacts 130 of the fourth volatile memory device 106d of the first deck 102 along the Z direction. In some implementations, the connection structures 113a of the first non-volatile memory device 114a are coupled to corresponding conductive channels 129 of the first deck 102 through the conductive bumps 117 and the metal contacts 130.

In some implementations, the conductive bumps 117 are encapsulate by the insulation material 119. The insulation material 119 can include, but not limited to non-conductive film (NCF), epoxy resin, non-conductive adhesive or any suitable material thereof. The insulation material 119 can have various forms including but not limited to solid form, particle form, and liquid form. In some implementations, the encapsulation can be used to provide physical support of the conductive bumps 117 and the metal contacts 130. In some implementations, the insulation material 119 can be used to dissipate heat generated by the conductive bumps 117 and the metal contacts 130 during an operation of the semiconductor device 100a.

FIG. 1E illustrates a cross-sectional view of a 3D semiconductor device 100e. The semiconductor device 100e can be similar to the semiconductor device 100a of FIG. 1A.

As shown in FIG. 1E, the semiconductor device 100a includes a first deck 102 of volatile memory device (e.g., DRAM) and a second deck 104 of non-volatile memory device (e.g., NAND flash memory). The first deck 102 includes a first volatile memory device 106a, a second volatile memory device 106b, a third volatile memory device 106c, and a fourth volatile memory device 106d (collectively referred to as volatile memory devices 106) stacked along a vertical direction (e.g., the Z direction). Adjacent volatile memory devices of the volatile memory devices 106a-106d are bonded through a respective bonding layer. For example, the volatile memory devices 106a and 106b are bonded through a first bonding layer 108a in between. In some implementations, the first bonding layer 108a includes conductive bonding contacts 110 and a dielectric material 111 isolating the conductive bonding contacts 110. The volatile memory devices 106b and 106c are bonded through a second bonding layer 108b in between. The volatile memory devices 106c and 106d are bonded through a third bonding layer 108c in between. In some implementations, the second bonding layer 108b and the third bonding layer 108c can be similar to, or same as the first bonding layer 108a. In some implementations, each of the volatile memory devices 106 of the semiconductor device 100a can include connection structures extending along the Z direction. For example, the first volatile memory device 106a includes connection structures 112a (also referred to as first connection structures), the second volatile memory device 106b includes connection structures 112b (also referred to as second connection structures), the third volatile memory device 106c includes connection structures 112c, and the fourth volatile memory device 106d includes connection structures 112d. In some implementations, the connection structures 112a are coupled to the conductive bonding contacts 110 in the first bonding layer 108a, the connection structures 112b are coupled to corresponding conductive bonding contacts in the first bonding layer 108a and the second bonding layer 108b, the connection structures 112c are coupled to corresponding conductive bonding contacts in the second bonding layer 108b and the third bonding layer 108c, and the connection structures 112d are coupled to corresponding conductive bonding contacts in the third bonding layer 108c along the Z direction.

In some implementations, each of the volatile memory devices 106a-106d can include a first semiconductor structure including an array of DRAM cells and a second semiconductor structure including a peripheral circuit configured to control the array of DRAM cells. In some implementations, the first semiconductor structure and the second semiconductor structure are stacked along the Z direction and are bonded through a second bonding layer in between. In some implementations, the second bonding layer includes conductive bonding contacts similar to the conductive bonding contacts 110 and a dielectric material isolating the conductive bonding contacts.

It is understood that FIG. 1E is for illustration propose only. While the first deck 102 in FIG. 1E includes four volatile memory devices 106a-106d, in practice, the first deck 102 can include any number of volatile memory devices similar to each of the volatile memory devices 106a-106d.

The second deck 104 is stacked on the first deck 102 along the Z direction. In some implementations, as shown in FIG. 1E, the second deck 104 includes a first non-volatile memory device 114a, a second non-volatile memory device 114b, a third non-volatile memory device 114c, and a fourth non-volatile memory device 114d. The non-volatile memory devices 114a-114d (collectively referred to as non-volatile memory devices 114) are stacked along the vertical direction. Adjacent non-volatile memory devices of the non-volatile memory devices 114a-114d are bonded through respective conductive bumps in between. In some implementations, the conductive bumps are isolated by an insulation material. In some implementations, the insulation material can be formed using a non-conductive film (NCF) or using a liquid underfill material and a thermal curing process. For example, the second non-volatile memory device 114b is stacked on the first non-volatile memory device 114a along the Z direction and bonded through conductive bumps 116a in between. The third non-volatile memory device 114c is stacked on the second non-volatile memory device 114b along the Z direction and bonded through conductive bumps 116b in between. The fourth non-volatile memory device 114d is stacked on the third non-volatile memory device 114c along the Z direction and bonded through conductive bumps 116c in between. Each of the non-volatile memory devices 114a-114d of the semiconductor device 100a can include connection structures extending along the Z direction. For example, the first non-volatile memory device 114a includes connection structures 113a (also referred to as third connection structures), the second non-volatile memory device 114b includes connection structures 113b, and the third non-volatile memory device 114c includes connection structures 113c. In some implementations, the conductive bumps 116a – 116c can be microbumps. In some implementations, the connection structures 113a extend through the first non-volatile memory device 114a and are coupled to the conductive bumps 116a along the Z direction, the connection structures 113b extend through the second non-volatile memory device 114b and are coupled to the conductive bumps 116a and 116b along the Z direction, and the connection structures 113c extend through the third non-volatile memory device 114c and are coupled to the conductive bumps 116b and 116c along the Z direction.

In some implementations, the conductive bumps 116a are coupled to the connection structures 113b in the second non-volatile memory device 114b, and the connection structures 113a extending along the Z direction in the first non-volatile memory device 114a.

In some implementations, as shown in FIG. 1E, the first deck 102 and the second deck 104 are coupled through conductive bumps 117 along the Z direction (also referred to as second conductive bumps). The conductive bumps 117 are isolated by an insulation material 119. In some implementations, the insulation material 119 can be formed using a non-conductive film (NCF) or using a liquid underfill material and a thermal curing process. In some implementations, the connection structures 113a are coupled to the conductive bumps 117 along the Z direction. In some implementations, the conductive bumps electrical coupled the connection structures 113a in the first non-volatile memory device 114a and the connection structures 112d in the fourth volatile memory device 106d together along the Z direction.

In some implementations, each of the non-volatile memory devices 114a – 114d can include a first semiconductor structure including an array of NAND flash memory cells and a second semiconductor structure including a peripheral circuit configured to control the array of NAND flash memory cells. In some implementations, the first semiconductor structure and the second semiconductor structure are stacked along the Z direction and are bonded through a third bonding layer in between. In some implementations, the third bonding layer includes conductive bonding contacts and a dielectric material isolating the conductive bonding contacts.

It is understood that FIG. 1E is for illustration propose only. While the second deck 104 in FIG. 1E includes four non-volatile memory devices 114a-114d, in practice, the second deck 104 can include any number of volatile memory devices similar to each of the non-volatile memory devices 114a-114d.

In some implementations, the semiconductor device 100a can be used to store different types of data based on access frequency. The data can be categorized into hot data, warm data, and cold data. The hot data have high access frequency with a relatively low data size, which can be stored in the stack 102 of the volatile memory devices 106a – 106d. The volatile memory devices 106a – 106d can provide a high access speed for the hot data with a relatively low storage capacity. The warm data have medium access frequency with medium data size and the cold data have low access frequency with large data size. The warm and cold data can be stored in the stack 104 of non-volatile memory devices 114a – 114b. The non-volatile memory devices 114a – 114b can provide a high storage capacity with a relative low access speed.

As shown in FIG. 1E, the logic device 118 can be bounded to the interposer 120 adjacent to the first deck 102 and the second deck 104 along a horizontal direction (e.g., the Y direction) perpendicular to the Z direction. In some implementations, the logic device 118 is coupled to the first deck 102 and the second deck 104 through the interposer 120. In some implementations, the logic device 118 and the first deck 102 are coupled to the interposer 120 by conductive bumps 135. The logic device 118 is configured to control the first deck 102 and the second deck 104 through the connection structures 112a-112d and the connection structures 113a – 113c. In some implementations, the logic device 118 is configured to transmit data between the decks 102, 104 and a computing device. In some implementations, the logic device 118 can include buffer circuitry and test logic for the first deck 102 of volatile memory devices 106 and the second deck 104 of non-volatile memory devices 114. In some implementations, the logic device 118 also includes a judgment module that is configured to categorize the data into hot data, warm data, and cold data based on access frequency.

In some implementations, the semiconductor device can be used to store different types of data that are categorized by access frequency. The data can be categorized into hot data, warm data, and cold data. The hot data has high access frequency, which requires high access speed. The warm data and the cold data have relatively low access frequency. For example, the hot data can be stored in the first deck 102 of the volatile memory device, which enables a high access speed for the hot data. In another example, the warm data and the cold data can be stored in the second deck 104 of the non-volatile memory device, which provides a high storage capacity with a relative lower access speed compared to the volatile memory device in the first deck 102.

In some implementations, as shown in FIG. 1A, the semiconductor device 100a also includes an interposer 120. In some implementations, the interposer 120 can be a printed circuit board (PCB). In some implementations, as shown in FIG. 1A, the first deck 102, the second deck 104, and the logic device 118 are stacked on top of the interposer 120 along the Z direction. In some implementations, the logic device 118 is between the interposer 120 and the first deck 102 along the Z direction. The interposer 120 can be configured to couple the logic device 118, the first deck 102 of volatile memory devices 106, and the second deck 104 of non-volatile memory devices 114 to a computing device (not shown in FIG. 1A). The computing device can include at least one processor of an electronic device, such as a central processing unit (CPU), a graphics processing unit (GPU), an application-specific integrated circuit (ASIC), or a system-on-chip (SoC), such as an application processor (AP). In some implementations, the computing device can be an electrical device including but not limited to desktop computers, laptop computers, smartphones, tablets, and any suitable electrical device thereof. The computing device can be configured to send data to and/or receive data from the first deck 102 and/or the second deck 104 through different channels on the volatile memory devices 106a – 106d and non-volatile memory devices 114a – 114d. For example, each of the volatile memory devices 106a – 106d can include 16 channels and each of the channels has a 64 bits port configured to handle the hot data. In another example, the non-volatile memory devices 114a – 114d can include 8 channels and each of the channels has a 16 bits port configured to handle the warm data and the cold data. In some implementations, the computing device is also configured to transmit memory addresses, operation commands, and clock signals to the first deck 102 and/or the second deck 104 through the logic device 118.The interposer 120 can include interconnection lines that are coupled to the logic device 118 and the computing device. The logic device 118 can be configured to provide physical layer communication protocols (e.g., IEEE-1500) between the first deck 102 and/or the second deck 104 and the computing device. The logic device 118 can be configured to transmit data between the first deck 102 and/or the second deck 104 and the computing device based on control commands and addresses from the computing device.

FIG. 1F illustrates top views of the semiconductor device 100a along cut lines AA’ and BB’. As shown in FIG. 1F, the connection structures 112a in the first volatile memory device 106a are arranged into an array 132. The array 132 includes rows extending along the Y direction and columns extending along the X direction. The connection structures 112a can be spaced evenly along a plane perpendicular to the Z direction. A first pitch 131 is defined by a distance (e.g., a center-to-center distance) between two adjacent connection structures of the connection structures 112a in each of the rows of the array 132 along the Y direction. In some implementations, the volatile memory devices 106 of the semiconductor device 100a are bonded with a hybrid bonding method, where a range of the first pitch 131 is between 10 – 20 µm with a critical dimeson in a range of 4-5 µm. The connection structures 113a in the first non-volatile memory device 114a are arranged into an array 134. The array 134 includes rows extending along the Y direction and columns extending along the X direction. The connection structures 113a in the array 134 are spaced evenly along a plane perpendicular to the Z direction. A second pitch 133 is defined by a distance (e.g., a center-to-center distance) between two adjacent connection structures of the connection structures 113a. In some implementations, the non-volatile memory devices 114 of the semiconductor device 100a are bonded by microbumps, where a range of the second pitch 133 is between 20 – 50 µm with a critical dimeson greater than 10 µm. In some implementations, a length of the first pitch 131 in the first volatile memory device 106a is smaller than the second pitch 133 in the first non-volatile memory device 114a.

The first volatile memory device 106a includes a first device area 136a, a second device area 136b, and a connection area 136c. The array 132 is in the connection area 136c. In some implementations, as shown in FIG. 1F, the connection area 136c is between the first device area 136a and the second device area 136b along the Y direction. In some implementations (not shown in FIG. 1F), the semiconductor device 100a can include two connection areas and one device area. The device area is between the two connection regions along the Y direction. The first non-volatile memory device 114a includes a first device area 138a, a second device area 138b, and a connection area 138c. The array 134 is in the connection area 138c. In some implementations, as shown in FIG. 1F, the connection area 138c is between the first device area 138a and the second device area 138b along the Y direction.

In some implementations, as shown in FIG. 1F, the connection structures 112a of the array 132 in the first volatile memory device 106a include signal input/output (I/O) connection structures 137a in the connection area 136c and power I/O connection structures 137b in the first device area 136a, the second device area 136b, and the connection area 136c. The signal I/O connection structures 137a are configured to provide data path signals to the first volatile memory device 106a, and the power I/O connection structures 137b are configured to provide power supplies to the first volatile memory device 106a. In some implementations (not shown in FIG. 1F), the connection area 136c can include the signal I/O connection structures 137a for the first device area 136a and the second device area 136b and the power I/O connection structures 137b are only arranged in the first device area 136a and the second device area 136b. The arrangement of the power I/O connection structures 137b in the first device area 136a and the second device area 136b can optimize power supply network and reduce power consumption of the semiconductor device 100a. In some implementations, both the signal I/O connection structures 137a and the power I/O connection structures 137b are arranged in the connection area 136c. In some implementations, the signal I/O connection structures 137a and the power I/O connection structures 173b can be arranged in different locations in the volatile memory devices 106a – 106d based on a design of the logic device 118.

In some implementations, as shown in FIG. 1F, the connection structures 113a of the array 134 in the first non-volatile memory device 114a also includes signal I/O connection structures 139a (also referred to as I/O pins) that are configured to provide data path signals to the first non-volatile memory device 114a and the power I/O connection structures 139b (also referred to as power pins) that are configured to provide power supplies to the first non-volatile memory device 114a. In some implementations, as shown in FIG. 1F, the connection area 138c can include the signal I/O connection structures 139a for the first device area 138a and the second device area 138b and the power I/O connection structures 139b are arranged in the first device area 138a and the second device area 138b. The arrangement of the power I/O connection structures in the first device area 138a and the second device area 138b can optimize power supply network and reduce power consumption of the semiconductor device 100a. In some implementations (not shown in FIG. 1F), the signal I/O connection structures 139a and the power I/O connection structures 139b for the first device area 138a and the second device area 138b are both inside the connection region 138c. In some implementations, the signal I/O connection structures 139a and the power I/O connection structures 139b can be arranged in different locations in the non-volatile memory devices 114a – 114d based on a design of the logic device 118.

In some implementations, the volatile memory devices 106a – 106d are configured to store hot data which requires high data access speed and the non-volatile memory device 114a – 114d are configured to store warm data and cold data which requires a relatively low data access speed compared to the hot data. In some implementations, each of the non-volatile memory devices 114a – 114d has at least 256 I/O pins including eight channels and 16 bits per channel. Each of the volatile memory devices 106a – 106b has at least 1024 I/O pins including sixteen channels and 64 bits per channel. High I/O pins of the volatile memory devices 106a – 106b can provide high access speed, which can be used to store the hot data.

FIG. 2A illustrates a cross-sectional view of a 3D semiconductor device 200a. The semiconductor device 200a can include a stack of volatile memory devices such as a 3D dynamic random-access memory (DRAM) and non-volatile memory devices such as a NAND flash memory device. It is understood that FIG. 2A is for illustrative purposes only and may not necessarily reflect the actual device structure (e.g., interconnections) in practice.

As shown in FIG. 2A, the semiconductor device 200a includes a first deck 202 of volatile memory device (e.g., DRAM) and a second deck 204 of non-volatile memory device (e.g., NAND flash memory). The first deck 202 includes a first volatile memory device 206a, a second volatile memory device 206b, a third volatile memory device 206c and a fourth volatile memory device 206d (collectively referred to as volatile memory devices 206) stacked along a vertical direction (e.g., the Z direction). Adjacent volatile memory devices of the volatile memory devices 206a-206d are bonded through a respective bonding layer. For example, the volatile memory devices 206a and 206b are bonded through a first bonding layer 208a in between. In some implementations, the first bonding layer 108a includes a dielectric material and excludes a conductive bonding contact. The volatile memory devices 206b and 206c are bonded through a second bonding layer 208b in between. The volatile memory devices 206c and 206d are bonded through a third bonding layer 208c in between. In some implementations, the second bonding layer 208b and the third bonding layer 208c can be similar to, or same as the first bonding layer 208a.

The first deck 202 further includes connection structures 210, a first contact structure 211a, a second contact structure 211b, a third contact structure 211c, and a fourth contact structure 211d extending along the Z direction. The connection structures 210 extends through the first bonding layers 208a – 208c. The first contact structure 211a extends through the first bonding layer 208a and is coupled to the second volatile memory device 206b, the second contact structure 211b extends into and is coupled to the first volatile memory device 206a without extending through the first bonding layer 208, the third contact structure 211c extends through the first bonding layer 208a, the second bonding layer 208b and is coupled to the third volatile memory device 206c, and the fourth contact structure 211d extends through the first bonding layer 208a, the second bonding layer 208b, the third bonding layer 208c and is coupled to the fourth volatile memory device 206d. In some implementations, the first contact structure 211a can be coupled to an interconnect layer of the second volatile memory device 206b, the second contact structure 211b can be coupled to an interconnect layer of the first volatile memory device 206a, the third contact structure 211c can be coupled to an interconnect layer of the third volatile memory device 206c, and the fourth contact structure 211d can be coupled to an interconnect layer of the fourth volatile memory device 206d.

It is understood that FIG. 2A is for illustration propose only. While the first deck 202 in FIG. 2A includes four volatile memory devices 206a-206d, in practice, the first deck 202 can include any number of volatile memory devices similar to each of the volatile memory devices 206a-206d.

The second deck 204 of non-volatile memory devices 214 is stacked on the first deck 202 along the Z direction. The second deck 204 includes a first non-volatile memory device 214a, a second non-volatile memory device 214b, a third non-volatile memory device 214c, and a fourth non-volatile memory device 214d (collectively referred to as non-volatile memory devices 214) stacked along the Z direction. Adjacent non-volatile memory devices of the non-volatile memory devices 214a – 214d are bonded through respective bonding layers. For example, the non-volatile memory devices 214a and 214b are bonded through a bonding layer 216a in between. The bonding layer 216a includes conductive bonding contacts 218 and a dielectric material 220 isolating the conductive bonding contacts. The non-volatile memory devices 214b and 214c are bonded through a bonding layer 216b in between. The non-volatile memory devices 214c and 214d are bonded through a bonding layer 216c in between. In some implementations, the bonding layers 216b and 216c can be similar to, or same as the bonding layer 216a.

In some implementations, the conductive bonding contacts 218 in the bonding layer 216a are coupled to the second non-volatile memory device 214b and connection structures 212a along the Z direction in the first non-volatile memory device 214a. In some implementations, as shown in FIG. 2A, the connection structures 212a in the first non-volatile memory device 214a are coupled to the connection structures 210 in the first deck 202. In some implementations, the connection structures 210 and the connection structures 212a are used as signal channels for the second deck 204 of the non-volatile memory devices 214. In some implementations, connection structures 212b in the second non-volatile memory device 214b are coupled to the connection structures 212a in the first non-volatile memory device 214a through corresponding conductive bonding contacts of the bonding layer 216a and connection structures 212c in the third non-volatile memory device 214c through corresponding conductive bonding contacts of the bonding layer 216b. In some implementations, the connection structures 212c is coupled to the fourth non-volatile memory device 214d through corresponding conductive bonding contacts of the bonding layer 216c.

It is understood that FIG. 2A is for illustration propose only. While the second deck 204 in FIG. 2A includes four non-volatile memory devices 214a-214d, in practice, the second deck 204 can include any number of non-volatile memory devices similar to each of the non-volatile memory devices 214a-214d.

In some implementations, the semiconductor device 200a can be used to store different types of data based on access frequency. The data can be categorized into hot data, warm data, and cold data. The hot data have high access frequency with a relatively low data size, which can be stored in the stack 202 of the volatile memory devices 206a – 206d. The volatile memory devices 206a – 206d can provide a high access speed for the hot data with a relatively low storage capacity. The warm data have medium access frequency with medium data size and the cold data have low access frequency with large data size. The warm and cold data can be stored in the stack 204 of non-volatile memory devices 214a – 214b. The non-volatile memory devices 214a – 214b can provide a high storage capacity with a relative low access speed.

In some implementations, the semiconductor device 200a can further includes a logic device 224 coupled to the first deck 202 and the second deck 204. In some implementations, the logic device 224 can include logic circuits that are configured to control the first deck 202 of volatile memory devices 206 and the second deck 204 of non-volatile memory devices 214. In some implementations, the logic device 224 includes a control circuit module. The control circuit module includes an access frequency judgement unit configured to determine an access frequency of a data unit stored in the first deck 202 or the second deck 204. In some implementations, as shown in FIG. 2A, the first deck 202 and the second deck 204 are stacked on top of the logic device 224 along the Z direction. In some implementations, the logic device 224 can include buffer circuitry and test logic for the first deck 202 of volatile memory devices 206 and the second deck 204 of non-volatile memory devices 214.

In some implementations, as shown in FIG. 2A, the semiconductor device 200a also includes an interposer 226. In some implementations, the interposer 226 can be a printed circuit board (PCB). In some implementations, as shown in FIG. 2A, the first deck 202, the second deck 204, and the logic device 224 are stacked on top of the interposer 226 along the Z direction. In some implementations, the logic device 224 is between the first deck 202 and the interposer 226 along the Z direction. The interposer 226 can be configured to couple the logic device 224, the first deck 202 of volatile memory devices 206, and the second deck 204 of non-volatile memory devices 214 to a computing device (not shown in FIG. 2A). The computing device can include at least one processor of an electronic device, such as a central processing unit (CPU), a graphics processing unit (GPU), an application-specific integrated circuit (ASIC), or a system-on-chip (SoC), such as an application processor (AP). In some implementations, the computing device can be an electrical device including but not limited to desktop computers, laptop computers, smartphones, tablets, and any suitable electrical device thereof. The computing device can be configured to send data to and/or receive data from the first deck 202 and/or the second deck 204 through different channels on the volatile memory devices 206a – 206d and non-volatile memory devices 214a – 214d. For example, each of the volatile memory devices 206a – 206d can include 16 channels and each of the channels has a 64 bits port configured to handle the hot data. In another example, the non-volatile memory devices 214a – 214d can include 8 channels and each of the channels has a 16 bits port configured to handle the warm data and the cold data. In some implementations, the computing device is also configured to transmit memory addresses, operation commands, and clock signals to the first deck 202 and/or the second deck 204 through the logic device 224. The interposer 226 can include interconnection lines that are coupled to the logic device 224 and the computing device. The logic device 224 can be configured to provide physical layer communication protocols (e.g., IEEE-1500) between the first deck 202 and/or the second deck 204 and the computing device. The logic device 224 can be configured to transmit data between the first deck 202 and/or the second deck 204 and the computing device based on control commands and addresses from the computing device.

In some implementations, each of the volatile memory devices 206a – 206d can include a first semiconductor structure including an array of DRAM cells and a second semiconductor structure including a peripheral circuit configured to control the array of DRAM cells. In some implementations, the first semiconductor structure and the second semiconductor structure are stacked along the Z direction and are bonded through a third bonding layer in between. In some implementations, the third bonding layer includes conductive bonding contacts similar to the conductive bonding contacts 110 and a dielectric material isolating the conductive bonding contacts.

In some implementations, each of the non-volatile memory devices 214a – 214d can include a first semiconductor structure including an array of NAND flash memory cells and a second semiconductor structure including a peripheral circuit configured to control the array of NAND flash memory cells. In some implementations, the first semiconductor structure and the second semiconductor structure are stacked along the Z direction and are bonded through a fourth bonding layer in between. In some implementations, the fourth bonding layer includes conductive bonding contacts and a dielectric material isolating the conductive bonding contacts.

In some implementations, as shown in FIG. 2A, the first deck 202 and the second deck 204 are coupled through a bonding layer 228 in between. The bonding layer includes bonding contacts 230 and a dielectric material 231 isolating the bonding contacts 230.

FIG. 2B illustrates a cross-sectional view of a semiconductor device 200b. The semiconductor device 200b can be a zoomed in view of two adjacent volatile memory devices 206 (e.g., the first volatile memory device 206a and the second volatile memory device 206b) of the first deck 202 of the semiconductor device 200a of FIG. 2A. In some implementations, the first volatile memory device 206a and the second volatile memory device 206b can be bonded by the first bonding layer 208a. For example, the first bonding layer 208a can be formed with a direct bonding process or direct bonding technique. In some implementations, the first contact structure 211a, the third contact structure 211c, and a fourth contact structure 211d extends through the first bonding layer 208a.

The first bonding layer 208a includes only dielectric material and excludes conductive bonding contacts. In some implementations, the first bonding layer 208a can include a top bonding layer and a bottom bonding layer bonded at a bonding interface. In some implementations, the top bonding layer can be on top of the volatile memory device 206a and the bottom bonding layer is on bottom of the volatile memory device 206b. The volatile memory devices 206a and 206b are bonded together by connecting the top bonding layer and the bottom layer. Each of the top bonding layer and the bottom bonding layer can include a dielectric material (including, but not limited to, silicon oxide, silicon nitride, silicon oxynitride, low-k dielectrics, or any combination thereof) and can exclude a conductive bonding contact. The second volatile memory device 206b can be bonded on top of the first volatile memory device 206a in a face-to-face manner through the first bonding layer 208a. Bonding interface is disposed between the top bonding layer and the bottom bonding layer as a result of direct bonding (e.g., dielectric-dielectric bonding), which forms bonding between surfaces without using intermediate layers, such as solder or adhesives. In some implementations (not shown in FIG. 2B), for example, when the dielectric material of the top bonding layer and the dielectric material of the bottom bonding layer are different materials, bonding interface can be a visible layer with a certain thickness that includes a top surface of the bottom bonding layer and a bottom surface of the top bonding layer. In some implementations, as shown in the example of FIG. 2B, when the dielectric material of the top bonding layer and the dielectric material of the bottom bonding layer are the same material, bonding interface may not be visible and the top bonding layer and the bottom bonding layer may form a continuous first bonding layer 208a.

As shown in FIG. 2B, each of the first volatile memory device 206a and the second volatile memory device 206b can include a substrate and an interconnect layer. In some implementations, as shown in FIG. 2B, the first volatile memory device 206a includes the interconnect layer 232a and the substrate. The interconnect layer 232a and the substrate 232b are stacked along the Z direction. The second contact structure 211b of the first volatile memory device 206a can extend into the interconnect layer 232a without extend into the substrate 232b. The interconnect layer 232a can include interconnects (also referred to herein as “contacts”), including interconnect lines 232a-1. The second contact structure 211b can be coupled to the interconnect lines 232a-1 in the interconnect layer 232a. As used herein, the term “interconnects” can broadly include any suitable types of interconnects, such as middle-end-of-line (MEOL) interconnects and back-end-of-line (BEOL) interconnects. The interconnect layer 232a can further include one or more interlayer dielectric (ILD) layers (also known as “intermetal dielectric (IMD) layers”) in which the interconnect lines 232a-1 can form. The interconnect lines 232a-1 contacts in the interconnect layer 232a can include conductive materials including, but not limited to, tungsten (W), cobalt (Co), copper (Cu), aluminum (Al), silicides, or any combination thereof. The ILD layers in the interconnect layer 232a can include dielectric materials including, but not limited to, silicon oxide, silicon nitride, silicon oxynitride, low dielectric constant (low-k) dielectrics, or any combination thereof. The substrate 232b can be any suitable semiconductor substrate having any suitable semiconductor materials, such as monocrystalline, polycrystalline or single crystalline semiconductors. For example, the substrate 232b can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof.

In some implementations, as shown in FIG. 2B, the second volatile memory device 206b includes the interconnect layer 234a and the substrate 234b. The interconnect layer 234a and the substrate 234b are stacked along the Z direction. The first contact structure 211a extends through the first volatile memory device 206a, the first bonding layer 208a and into the interconnect layer 234a of the second volatile memory device 206b. In some implementations, the interconnect layer 234a can be similar to, or same as the interconnect layer 232a. In some implementations, the substrate 234b can be similar to, or same as the substrate 232b.

FIG. 2C illustrates a cross-sectional view of a semiconductor device 200c. The semiconductor device 200c can be a zoomed in view of two adjacent non-volatile memory devices 214 (e.g., the first non-volatile memory device 214a and the second non-volatile memory device 214b) of the second deck 204 of the semiconductor device 200a of FIG. 2A. In some implementations, the first non-volatile memory device 214a and the second non-volatile memory device 214b can be bonded by the bonding layer 216a through conductive bonding contacts 218. In some implementations, the connection structures 212a and the connection structures 212b are electrically coupled together through the conductive bonding contacts 218 along the Z direction.

In some implementations, as shown in FIG. 2C, each of the first non-volatile memory devices 214a and the second non-volatile memory device 214b can include a substrate and an interconnect layer stacked along the Z direction. In some implementations, as shown in FIG. 2C, the first non-volatile memory device 214a includes the interconnect layer 236a and the substrate 236b. The interconnect layer 236a and the substrate 236b are stacked along the Z direction. The connection structures 212a of the first non-volatile memory device 214a can extend though the substrate 236b and can be coupled to the interconnect layer 236a. In some implementations, the interconnect layer 236a can be similar to, or same as the interconnect layer 122a of FIG. 1B. In some implementations, the substrate 236b can be similar to, or same as the substrate 122b of FIG. 1B.

In some implementations, as shown in FIG. 2C, the second non-volatile memory device 214b includes the interconnect layer 238a and the substrate 238b. The interconnect layer 238a and the substrate 238b are stacked along the Z direction. The connection structures 212b of the second non-volatile memory device 214b can extend though the substrate 238b and can be coupled to the interconnect layer 238a and the connection structures 212a along the Z direction. In some implementations, the connection structures 212b can be similar to, or same as the connection structures 212a. In some implementations, the interconnect layer 238a can be similar to, or same as the interconnect layer 122a of FIG. 1B. In some implementations, the substrate 238b can be similar to, or same as the substrate 122b of FIG. 1B.

FIG. 2D illustrates a cross-sectional view of a semiconductor device 200d. The semiconductor device 200d can be a zoomed on zone C of the semiconductor device 200a of FIG. 2A.

As shown in FIG. 2D, the first non-volatile memory device 214a of the second deck 204 is stacked on top of the fourth volatile memory device 206d of the first deck 202. The first non-volatile memory device 214a and the fourth volatile memory device 206d are bonded together through the bonding layer 228 in between. In some implementations, the bonding layer 228 can be referred to as a hybrid bonding layer since it can be formed through hybrid dielectric-dielectric bonding and metal-metal bonding. The hybrid bonding technique can form bonding between surfaces without using intermediate layers, such as solder or adhesives and can obtain metal-metal bonding and dielectric-dielectric bonding simultaneously. In some implementations, as shown in FIG. 2D, the bonding layer 228 includes bonding contacts 230 and a dielectric material 231 isolating the bonding contacts 230. In some implementations, as shown in FIG. 2D, the connection structures 210 in the fourth volatile memory device 206d and the connection structures 212a in the first non-volatile memory device 214a are coupled together through the bonding contacts 230 of the bonding layer 228.

FIG. 2E illustrates a cross-sectional view of a 3D semiconductor device 200e. The semiconductor device 200e can be similar to the semiconductor device 200a of FIG. 2A.

As shown in FIG. 2E, the semiconductor device 200e includes a first deck 202 of volatile memory device (e.g., DRAM) and a second deck 204 of non-volatile memory device (e.g., NAND flash memory). The first deck 202 includes a first volatile memory device 206a, a second volatile memory device 206b, a third volatile memory device 206c and a fourth volatile memory device 206d (collectively referred to as volatile memory devices 206) stacked along a vertical direction (e.g., the Z direction). Adjacent volatile memory devices of the volatile memory devices 206a-206d are bonded through a respective bonding layer. For example, the volatile memory devices 206a and 206b are bonded through a first bonding layer 208a in between. In some implementations, the first bonding layer 208a includes a dielectric material and excludes a conductive bonding contact. The volatile memory devices 206b and 206c are bonded through a second bonding layer 208b in between. The volatile memory devices 206c and 206d are bonded through a third bonding layer 208c in between. In some implementations, the second bonding layer 208b and the third bonding layer 208c can be similar to, or same as the first bonding layer 208a.

The first deck 202 further includes connection structures 210, a first contact structure 211a, a second contact structure 211b, a third contact structure 211c, and a fourth contact structure 211d extending along the Z direction. The connection structures 210 extends through the first bonding layers 208a – 208c. The first contact structure 211a extends through the first bonding layer 208a and is coupled to the second volatile memory device 206b, the second contact structure 211b extends into and is coupled to the first volatile memory device 206a without extending through the first bonding layer 208, the third contact structure 211c extends through the first bonding layer 208a, the second bonding layer 208b and is coupled to the third volatile memory device 206c, and the fourth contact structure 211d extends through the first bonding layer 208a, the second bonding layer 208b, the third bonding layer 208c and is coupled to the fourth volatile memory device 206d. In some implementations, the first contact structure 211a can be coupled to an interconnect layer of the second volatile memory device 206b, the second contact structure 211b can be coupled to an interconnect layer of the first volatile memory device 206a, the third contact structure 211c can be coupled to an interconnect layer of the third volatile memory device 206c, and the fourth contact structure 211d can be coupled to an interconnect layer of the fourth volatile memory device 206d.

It is understood that FIG. 2E is for illustration propose only. While the first deck 202 in FIG. 2E includes four volatile memory devices 206a-206d, in practice, the first deck 202 can include any number of volatile memory devices similar to each of the volatile memory devices 206a-206d.

The second deck 204 of non-volatile memory devices 214 is stacked on the first deck 202 along the Z direction. The second deck 204 includes a first non-volatile memory device 214a, a second non-volatile memory device 214b, a third non-volatile memory device 214c, and a fourth non-volatile memory device 214d (collectively referred to as non-volatile memory devices 214) stacked along the Z direction. Adjacent non-volatile memory devices of the non-volatile memory devices 214a – 214d are bonded through respective bonding layers. For example, the non-volatile memory devices 214a and 214b are bonded through a bonding layer 216a in between. The bonding layer 216a includes conductive bonding contacts 218 and a dielectric material 220 isolating the conductive bonding contacts. The non-volatile memory devices 214b and 214c are bonded through a bonding layer 216b in between. The non-volatile memory devices 214c and 214d are bonded through a bonding layer 216c in between. In some implementations, the bonding layers 216b and 216c can be similar to, or same as the bonding layer 216a.

In some implementations, the conductive bonding contacts 218 in the bonding layer 216a are coupled to the second non-volatile memory device 214b and connection structures 212a along the Z direction in the first non-volatile memory device 214a. In some implementations, as shown in FIG. 2E, the connection structures 212a in the first non-volatile memory device 214a are coupled to the connection structures 210 in the first deck 202. In some implementations, the connection structures 210 and the connection structures 212a are used as signal channels for the second deck 204 of the non-volatile memory devices 214. In some implementations, connection structures 212b in the second non-volatile memory device 214b are coupled to the connection structures 212a in the first non-volatile memory device 214a through corresponding conductive bonding contacts of the bonding layer 216a and connection structures 212c in the third non-volatile memory device 214c through corresponding conductive bonding contacts of the bonding layer 216b. In some implementations, the connection structures 212c is coupled to the fourth non-volatile memory device 214d through corresponding conductive bonding contacts of the bonding layer 216c.

It is understood that FIG. 2E is for illustration propose only. While the second deck 204 in FIG. 2E includes four non-volatile memory devices 214a-214d, in practice, the second deck 204 can include any number of non-volatile memory devices similar to each of the non-volatile memory devices 214a-214d.

In some implementations, the semiconductor device 200a can be used to store different types of data based on access frequency. The data can be categorized into hot data, warm data, and cold data. The hot data have high access frequency with a relatively low data size, which can be stored in the stack 202 of the volatile memory devices 206a – 206d. The volatile memory devices 206a – 206d can provide a high access speed for the hot data with a relatively low storage capacity. The warm data have medium access frequency with medium data size and the cold data have low access frequency with large data size. The warm and cold data can be stored in the stack 204 of non-volatile memory devices 214a – 214b. The non-volatile memory devices 214a – 214b can provide a high storage capacity with a relative low access speed.

As shown in FIG. 2E, the semiconductor 200e further includes a logic device 224. The logic device 224 can be bounded to the interposer 226 adjacent to the first deck 202 and the second deck 204 along a horizontal direction (e.g., the Y direction) perpendicular to the Z direction. In some implementations, the logic device 224 is coupled to the first deck 202 and the second deck 204 through the interposer 226. The logic device 224 is configured to control the first deck 202 and the second deck 204 through the first contact structure 211a, the second contact structure 211b, the connection structures 210, and the second connection structures 212. In some implementations, the logic device 224 and the first deck 202 are coupled to the interposer 226 by conductive bumps 235. The logic device 224 is configured to control the first deck 202 and the second deck 204 through contact structures 211a – 211d and connection structures 212a – 212c.

In some implementations, as shown in FIG. 2E, the semiconductor device 200a also includes an interposer 226. In some implementations, the interposer 226 can be a printed circuit board (PCB). In some implementations, as shown in FIG. 2E, the first deck 202, the second deck 204, and the logic device 224 are stacked on top of the interposer 226 along the Z direction. In some implementations, the logic device 224 is between the first deck 202 and the interposer 226 along the Z direction. The interposer 226 can be configured to couple the logic device 224, the first deck 202 of volatile memory devices 206, and the second deck 204 of non-volatile memory devices 214 to a computing device (not shown in FIG. 2E). The computing device can include at least one processor of an electronic device, such as a central processing unit (CPU), a graphics processing unit (GPU), an application-specific integrated circuit (ASIC), or a system-on-chip (SoC), such as an application processor (AP). In some implementations, the computing device can be an electrical device including but not limited to a desktop computer, a laptop computer, a smartphone, a tablet, and any suitable electrical device thereof. The computing device can be configured to send data to and/or receive data from the first deck 202 and/or the second deck 204 through different channels on the volatile memory devices 206a – 206d and non-volatile memory devices 214a – 214d. For example, each of the volatile memory devices 206a – 206d can include 16 channels and each of the channels has a 64 bits port configured to handle the hot data. In another example, the non-volatile memory devices 214a – 214d can include 8 channels and each of the channels has a 16 bits port configured to handle the warm data and the cold data. In some implementations, the computing device is also configured to transmit memory addresses, operation commands, and clock signals to the first deck 202 and/or the second deck 204 through the logic device 224. The interposer 226 can include interconnection lines that are coupled to the logic device 224 and the computing device. The logic device 224 can be configured to provide physical layer communication protocols (e.g., IEEE-1500) between the first deck 202 and/or the second deck 204 and the computing device. The logic device 224 can be configured to transmit data between the first deck 202 and/or the second deck 204 and the computing device based on control commands and addresses from the computing device.

In some implementations, each of the volatile memory devices 206a – 206d can include a first semiconductor structure including an array of DRAM cells and a second semiconductor structure including a peripheral circuit configured to control the array of DRAM cells. In some implementations, the first semiconductor structure and the second semiconductor structure are stacked along the Z direction and are bonded through a third bonding layer in between. In some implementations, the third bonding layer includes conductive bonding contacts similar to the conductive bonding contacts 110 and a dielectric material isolating the conductive bonding contacts.

In some implementations, each of the non-volatile memory devices 214a – 214d can include a first semiconductor structure including an array of NAND flash memory cells and a second semiconductor structure including a peripheral circuit configured to control the array of NAND flash memory cells. In some implementations, the first semiconductor structure and the second semiconductor structure are stacked along the Z direction and are bonded through a fourth bonding layer in between. In some implementations, the fourth bonding layer includes conductive bonding contacts and a dielectric material isolating the conductive bonding contacts.

In some implementations, as shown in FIG. 2E, the first deck 202 and the second deck 204 are coupled through a bonding layer 228 in between. The bonding layer includes bonding contacts 230 and a dielectric material 231 isolating the bonding contacts 230.

FIG. 2F illustrates top views of the semiconductor device 100a along cut lines AA’ and BB’. As shown in FIG. 2F, the connection structures 210 and the contact structures 211a – 211d in the first volatile memory device 206a are arranged into an array 240. The array 240 includes rows extending along the Y direction and columns extending along the X direction. The connection structures 210 or the contact structures 211a – 211d in the array 240 are spaced evenly along a plane perpendicular to the Z direction. A first pitch 242 is defined by a distance (e.g., a center-to-center distance) between each of the connection structures 210 or each of the contact structures 211a – 211d to an adjacent connection structure 210 or the contact structures 211a – 211d in each of the rows of the array 240 along the Y direction. In some implementations, the volatile memory devices 206 of the semiconductor device 200a are bonded with a direct bonding method, where a range of the first pitch 242 is between 5-10 µm with a critical dimeson in a range of 3-5 µm. The connection structures 212a in the first non-volatile memory device 214a are arranged into an array 244. The array 244 includes rows extending along the Y direction and columns extending along the X direction. The connection structures 212a in the array 244 are spaced evenly along a plane perpendicular to the Z direction. A second pitch 245 is defined by a distance (e.g., a center-to-center distance) between the two adjacent connection structures of the connection structures 212a in each of the rows of the array 244 along the Y direction. In some implementations, the non-volatile memory devices 214 of the semiconductor device 200a are bonded in with a hybrid bonding method, where a range of the second pitch 245 is between 10 – 20 µm with a critical dimeson in a range of 4-5 µm. In some implementations, a length of the first pitch 242 in the first volatile memory device 206a is smaller than the second pitch 245 in the first non-volatile memory device 214a.

The first volatile memory device 206a includes a first device area 246a, a second device area 246b, and a connection area 246c. The array 240 is in the connection area 246c. In some implementations, as shown in FIG. 2F, the connection area 246c is between the first device area 246a and the second device area 246b along the Y direction. The first non-volatile memory device 214a includes a first device area 248a, a second device area 248b, and a connection area 248c. The array 244 is in the connection area 248c. In some implementations, as shown in FIG. 2F, the connection area 248c is between the first device area 248a and the second device area 248b along the Y direction.

In some implementation, as shown in FIG. 2F, the contact structures 211a – 211d of the array 240 in the first volatile memory device 206a includes signal input/output (I/O) connection structures 247a in the connection area 246c and power I/O connection structures 247b in the first device area 246a, the second device area 246b, and the connection area 246c. The signal I/O connection structures 247a are configured to provide data path signals to the first volatile memory device 206a, and the power I/O connection structures 247b are configured to provide power supplies to the first volatile memory device 206a. In some implementations (not shown in FIG. 2F), the signal I/O connection structures 247a and the power I/O connection structures 247b for the first device area 246a and the second device area 246b are both inside the connection region 246c. In some implementations, the connection area 246c can include the signal I/O connection structures 247a for the first device area 246a and the second device area 246b and the power I/O connection structures 247b are arranged in the first device area 246a and the second device area 246b. The arrangement of the power I/O connection structures 247b in the first device area 246a and the second device area 246b can optimize power supply network and reduce power consumption of the semiconductor device 200a. In some implementations, the signal I/O connection structures 247a and the power I/O connection structures 247b can be arranged in different locations in the volatile memory devices 206a – 206d based on a design of the logic device 224.

In some implementations, the connection structures 212a of the array 244 in the first non-volatile memory device 214a is coupled to the connection structures 210 of the array 240 in the first volatile memory device 206a. The second connection structures 212 also includes signal I/O connection structures 249a (also referred to as I/O pins) that are configured to provide data path signals to the first non-volatile memory device 214a and the power I/O connection structures 249b (also referred to as power pins) that are configured to provide power supplies to the first non-volatile memory device 214a In some implementations, as shown in FIG. 2F, the connection area 248c can include the signal I/O connection structures 249a for the first device area 248a and the second device area 248b and the power I/O connection structures 249b are arranged in the first device area 248a and the second device area 248b. The arrangement of the power I/O connection structures 249b in the first device area 248a and the second device area 248b can optimize power supply network and reduce power consumption of the semiconductor device 200a. . In some implementations (not shown in FIG. 2F), the signal I/O connection structures 249a and the power I/O connection structures 249b for the first device area 248a and the second device area 248b are both inside the connection region 248c. In some implementations, the signal I/O connection structures 249a and the power I/O connection structures 249b can be arranged in different locations in the volatile memory devices 214a – 214d based on a design of the logic device 224.

In some implementations, as shown in FIG. 2A, the second deck 204 of the semiconductor device 200a includes four non-volatile memory devices 214 and at least 256 I/O connection structures, each of the four non-volatile memory devices 214 includes eight channels, and one of the eight channels includes at least six planes and eight I/O pins.

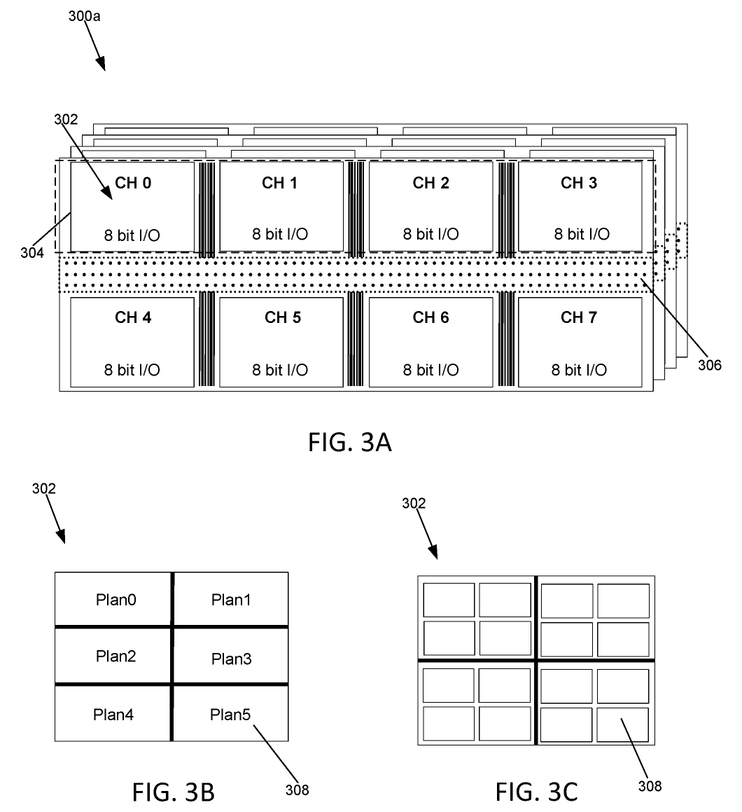

FIG. 3A illustrates an example of a circuit diagram of a memory device 300a. The memory device 300a can be a non-volatile memory device 114 of the semiconductor device 100a of FIG. 1A or a non-volatile memory device 214 of the semiconductor device 200a of FIG. 2A.

The memory device 300a can include one or more channels. Each channel can have multiple I/O connection structures. For example, as shown in FIG. 3A, the memory device 300a includes eight channels 302. The eight channels 302 are arranged into two rows 304 that are separated by an array of connection structures 306. In some implementations, the connection structures 306 can be similar to, or same as the connection structures 112b of the semiconductor device 100a of FIG. 1A or the second connection structures 212 of the semiconductor device 200a of FIG. 2A. In some implementations, the connection structures can include I/O connection structures that are configured to provide data path signals to corresponding channels 302 and power connection structures that are configured to provide power supplies to the corresponding channels 302. Each of the channels 302 includes at least six planes and eight I/O connection structures. In one example, the semiconductor device 100a of FIG. 1A includes four non-volatile memory device 114 and at least 256 I/O connection structures. In another example, the semiconductor device 200a of FIG. 2A includes four non-volatile memory device 214 and at least 256 I/O connection structures.

FIG. 3B illustrates a first layout of a channel 302. As shown in FIG. 3B, the channel 302 can include six planes 308 that are configured to store data. In some implementations, the first layout of the channel 302 is compatible with Complementary metal–oxide–semiconductor (CMOS) circuitry.

FIG. 3C illustrates a second layout of a channel 302. As shown in FIG. 3C, the channel 302 can include sixteen planes 308 that are configured to store data. In some implementations, the second layout of the channel 302 is configured to have a high data transfer speed compared to the first layout of the channel 302 of FIG. 3B. It is understood that FIGS. 3A-3C are for illustration propose only. In practice, the memory device 300a can include any suitable number of channels arranged in any suitable way.

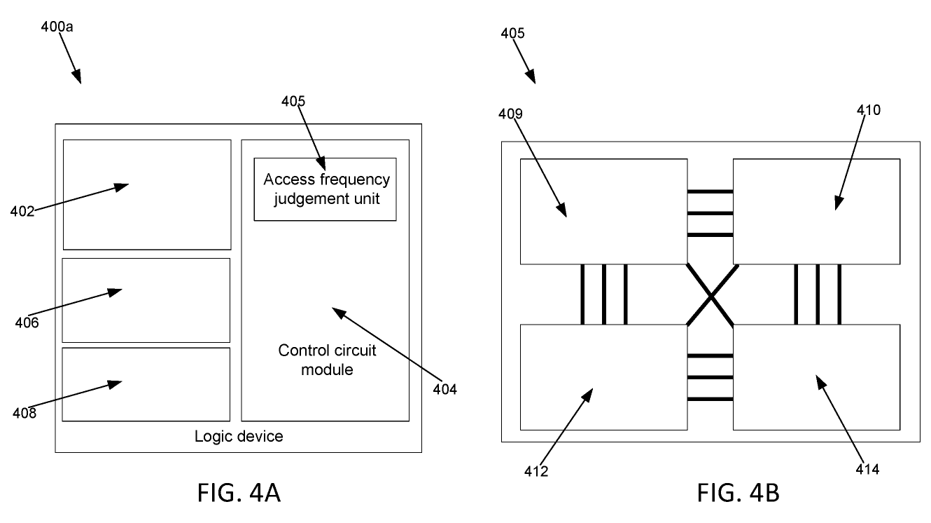

FIG. 4A illustrates a circuit diagram of a semiconductor device 400a. The semiconductor device 400a can be similar to, or same as the logic device 118 of the semiconductor device 100a of FIG. 1A or the logic device 224 of the semiconductor device 200a of FIG. 2A. In some implementations, the semiconductor device 400a is configured to control a memory device.

As shown in FIG. 4A, the semiconductor device 400a includes a computing module 402, a control module 404, a support module 406, and a power module 408. In some implementations, the computing module 402 is configured to perform computing functions, which satisfied a demand of AI computing such as near-memory computing. The control module 404 includes an access frequency judgement unit 405 that is configured to determine an access frequency of a data and configured to store the data into either a non-volatile memory device (e.g., the non-volatile memory devices 114 of FIG. 1A or the non-volatile memory devices 214 of FIG. 2A) or a volatile memory device (e.g., the volatile memory devices 106 of FIG. 1A or the volatile memory devices 206 of FIG. 2A) of the memory device. The power module 408 is configured to supply power to the semiconductor device 400a.

FIG. 4B illustrates a circuit diagram of the access frequency judgement unit 405 of the control module 404 of the semiconductor device 400a. As shown in FIG. 4B, the access frequency judgement unit 405 includes a counter circuit 409, a timer circuit 410, a comparator circuit 412, and an auxiliary circuit 414. In some implementations, the counter circuit 409, the timer circuit 410, the comparator circuit 412, and the auxiliary circuit 414 are coupled to each other to realize functions of the control module. In some implementations, the comparator circuit 412 can be used to determine an access frequency of a data. In one example, the comparator circuit 412 determines the access frequency of the data is high, the control module 404 is configured to control the memory device to store the data in a volatile memory device. In another example, the comparator circuit 412 determines the access frequency of the data is low, the control module 404 is configured to control the memory device to store the data in a non-volatile memory device. In some implementations, the data can be categorized into three categories based on the access frequency including hot data, warm data, and cold data. In some implementations, the hot data have high access frequency with low data size (e.g., lower than 500GB). Thus, the hot data can be stored in a volatile memory device (e.g., the volatile memory devices 106a – 106d of FIG. 1A) which can provide high access speed (e.g., greater than 20GB/s) with a relative low storage capacity. In some implementations, the warm data have medium access frequency with medium data size (e.g., around 10TB). Thus, the warm data can be stored in a non-volatile memory device (e.g., the non-volatile memory devices 114a – 114d of FIG. 1A) which can provide medium access speed (e.g., greater than 5GB/s) with a medium storage capacity. In some implementations, the cold data have low access frequency with high data size (e.g., greater than 50TB). Thus, the cold data can be stored in a non-volatile memory device (e.g., the non-volatile memory devices 114a – 114d of FIG. 1A) which can provide low access speed (e.g., greater than 500MB/s) with a high storage capacity.

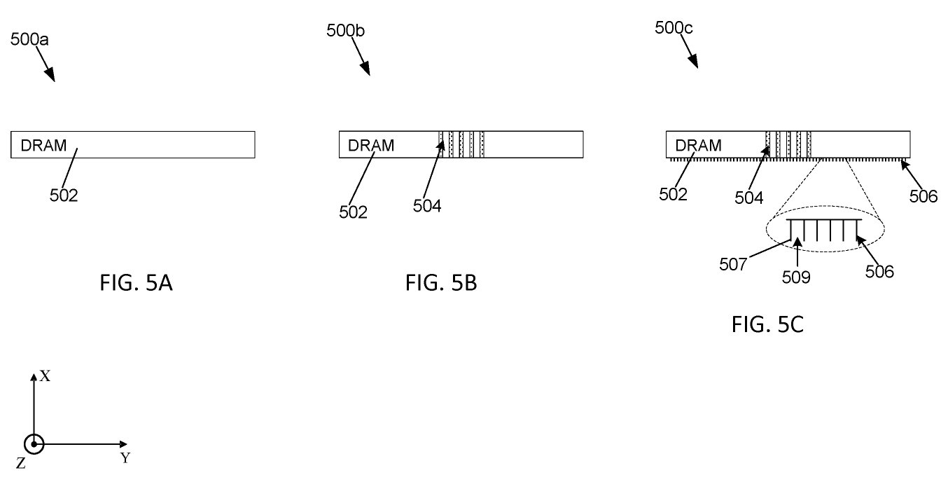

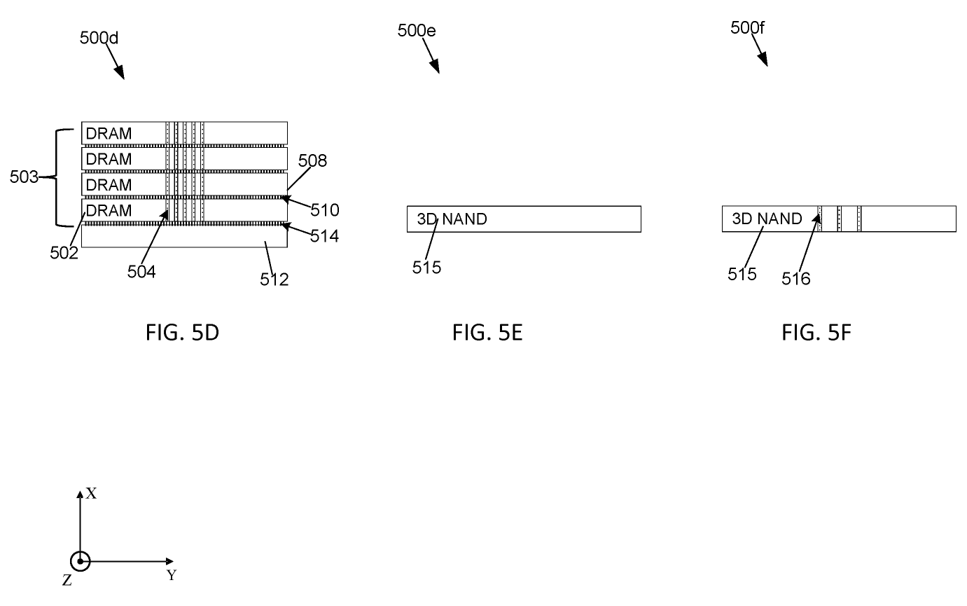

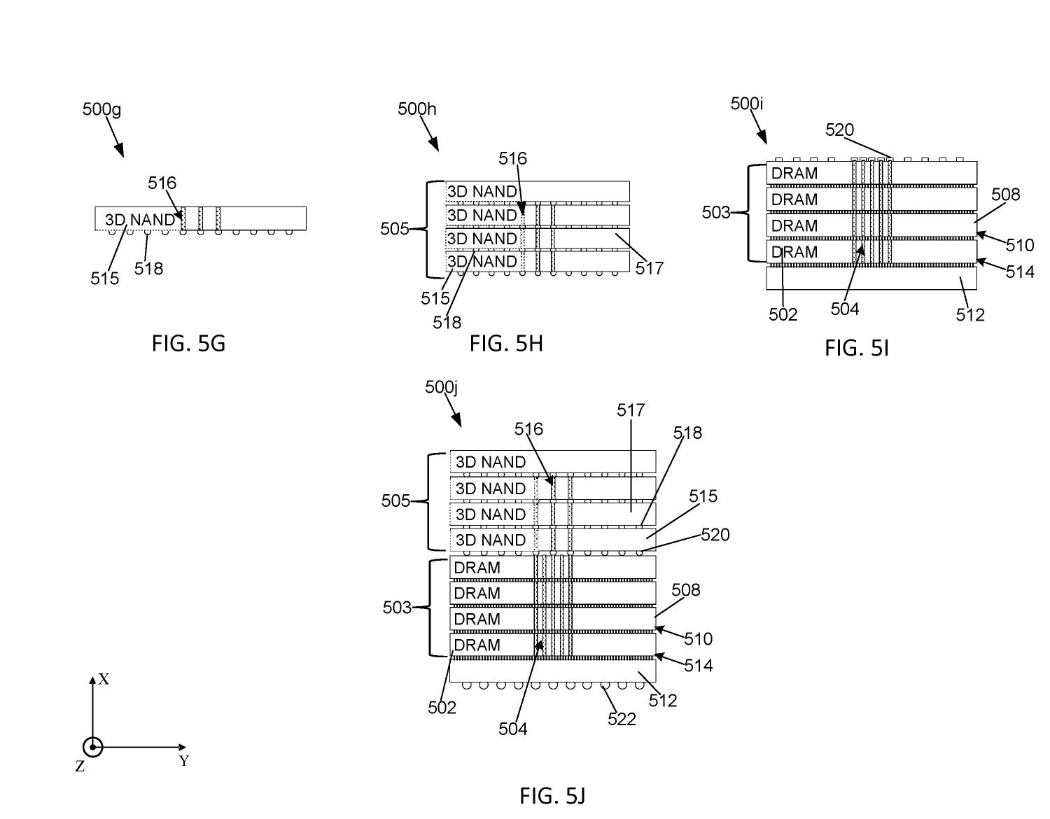

FIGS. 5A – 5J illustrate an example process of fabricating a semiconductor device, such as the semiconductor device 100a as illustrated in FIG. 1A. FIGS. 5A – 5J show cross-sectional views of example semiconductor structures at various stages of the fabrication process.

As shown in FIG. 5A, a semiconductor structure 500a is formed. In some implementations, the semiconductor structure 500a includes a first semiconductor structure 502. In some implementations, the first semiconductor structure 502 can be a volatile memory device such as a DRAM device.

FIG. 5B illustrates a semiconductor structure 500b, which can be formed by forming one or more connection structures 504 in a portion of the first semiconductor structure 502. In some implementations, the one or more connection structures 504 extend through the first semiconductor structure 502 along a vertical direction (e.g., the Z direction).

FIG. 5C illustrates a semiconductor structure 500c, which can be formed by forming a first sub-bonding layer 506 on one side of the first semiconductor structure 502. The first sub-bonding layer 506 includes conductive bonding contacts 507 and a dielectric material 509 isolating the conductive bonding contacts 507.

As shown in FIG. 5D, a semiconductor structure 500d is formed. The semiconductor structure 500d includes at least the first semiconductor structure 502 and a second semiconductor structure 508. In some implementations, the second semiconductor structure 508 can be similar to, or same as the first semiconductor structure 502. The semiconductor structure 500d can be formed by stacking the first semiconductor structure 502 and the second semiconductor structure 508 along the Z direction to form a first deck 503. The second semiconductor structure 508 includes a second sub-bonding layer having conductive bonding contacts and a dielectric material isolating the conductive bonding contacts. The first semiconductor structure 502 and the second semiconductor structure 508 can be bonded by align the semiconductor structure 502 and the second semiconductor structure 508 along the Z direction so that the conductive bonding contacts 507 of the first sub-bonding layer 506 is in contact with corresponding conductive bonding contacts of the second sub-bonding layer 508. The conductive bonding contacts 507 of the first sub-bonding layer 506 is coupled to the conductive bonding contacts of the second sub-bonding layer to form a first bonding layer 510.

In some implementations, the semiconductor structure 500d can include more semiconductor structures similar to the first semiconductor structure 502 and the second structures 504. As shown in FIG. 5D, the first deck 503 includes four semiconductor structures stacked on top of each other. The four semiconductor structures are bonded through bonding layers similar to the bonding layer 510. While in this example a semiconductor device can include four semiconductor structures stacked together, the technology disclosed herein can be applied to stacking any suitable number of semiconductor structures (e.g., 2, 5, or 8). The number of semiconductor structures can be determined based on factors including technology constraints, thermal considerations, signal integrity and interferences, physical size and application, costs and yields, reliability concerns, etc.

The semiconductor structure 500d also includes a logic device 512. The logic device 512 is staked with the first semiconductor structure 502 and the second semiconductor structure 508 along the Z direction. In some implementations, the logic device 512 is bonded with the first semiconductor structure 502 by a second bonding layer 514. In some implementations, the first semiconductor structure 502 and the second semiconductor structure 508 can be formed together on a wafer die, where the first semiconductor structure 502 and the second semiconductor structure 508 can be separated by cutting the wafer die by a dicing process.

As shown in FIG. 5E, a semiconductor structure 500e is formed. In some implementations, the semiconductor structure 500e includes a third semiconductor structure 515. In some implementations, the third semiconductor structure 515 can be a non-volatile memory device such as a NAND flash memory device.

FIG. 5F illustrates a semiconductor structure 500f, which can be formed by forming one or more connection structures 516 in a portion of the third semiconductor structure 515. In some implementations, the one or more connection structures 516 extend through the third semiconductor structure 515 along the Z direction.

FIG. 5G illustrates a semiconductor structure 500g, which can be formed by forming conductive bumps 518 on one side of the third semiconductor structure 515.

As shown in FIG. 5H, a semiconductor structure 500h is formed. The semiconductor structure 500h includes at least the third semiconductor structure 515 and a fourth semiconductor structure 517. In some implementations, the fourth semiconductor structure 517 can be similar to, or same as the third semiconductor structure 515. The semiconductor structure 500h can be formed by bonding the third semiconductor structure 515 and the fourth semiconductor structure 517 through the conductive bumps 518 to form a second deck 505. In some implementations, the third semiconductor structure 515 and the fourth semiconductor structure 517 can be formed together on a wafer die, where the third semiconductor structure 515 and the fourth semiconductor structure 517 can be separated by cutting the wafer die by a dicing process.

FIG. 5I illustrates a semiconductor structure 500i, which can be formed by forming conductive bonding contacts 520 on top of the first deck 503.

FIG. 5J illustrates a semiconductor structure 500j, which can be formed by stacking the first deck 503 and the second deck 505 along the Z direction through the conductive bonding contacts 520. In some implementations, the semiconductor structure 500j also includes second conductive terminal 522, which can be formed by forming second conductive terminal 522 on a side of the logic device 512. The side of the logic device 512 is further away from the first semiconductor structure 502 along the first direction.

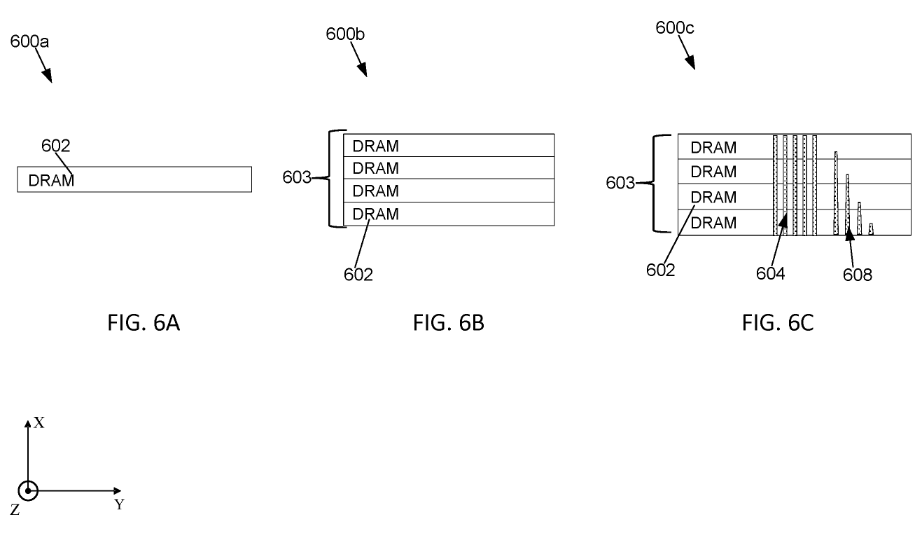

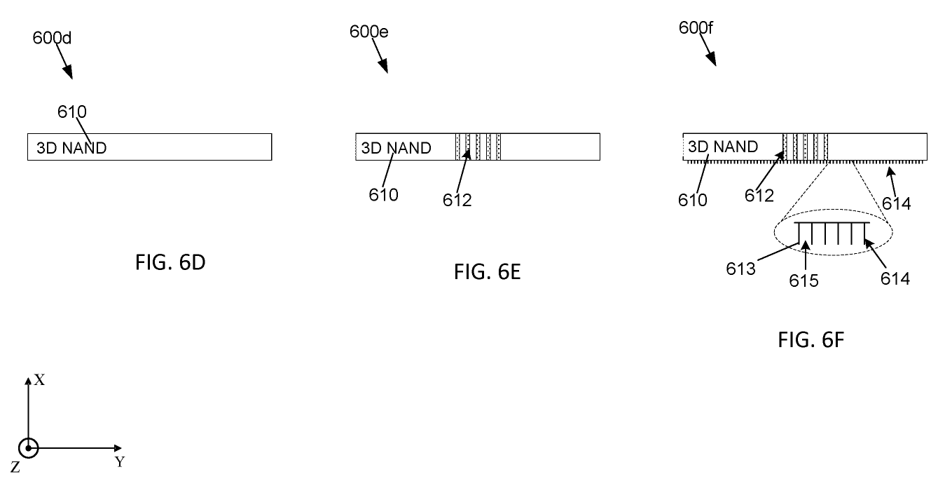

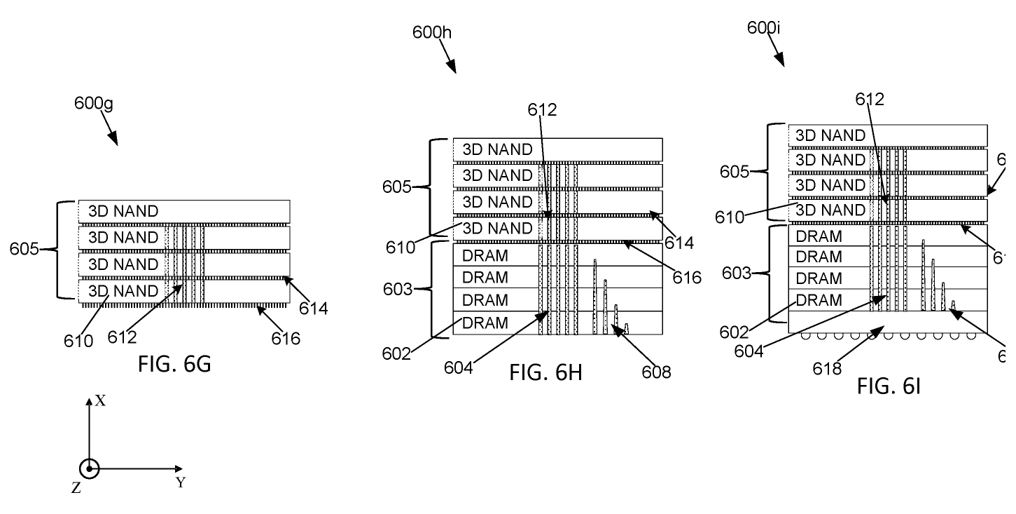

FIGS. 6A – 6I illustrate an example process of fabricating a semiconductor device, such as the semiconductor device 200a as illustrated in FIG. 2A. FIGS. 6A – 6J show cross-sectional views of example semiconductor structures at various stages of the fabrication process.

As shown in FIG. 6A, a semiconductor structure 600a is formed. In some implementations, the semiconductor structure 600a includes a first semiconductor structure 602. In some implementations, the first semiconductor structure 602 can be a volatile memory device such as a DRAM device.

FIG. 6B illustrates a semiconductor structure 600b, which can be formed by stacking one or more first semiconductor structures 602 on top of each other to form a first deck 603. As shown in FIG. 6B the first semiconductor structures 602 can be bonded with a direct bonding process. For example, a dielectric layer can be deposited on a bottom surface of semiconductor structure 602b, and a dielectric layer can be deposited on a top surface of semiconductor structure 602a. Semiconductor structure 602b can be stacked on and bonded to semiconductor structure 602a along the Z direction.

While in this example a semiconductor device can include four first semiconductor structures 602 stacked together, the technology disclosed herein can be applied to stacking any suitable number of semiconductor structures (e.g., 2, 5, or 8). The number of semiconductor structures can be determined based on factors including technology constraints, thermal considerations, signal integrity and interferences, physical size and application, costs and yields, reliability concerns, etc.

FIG. 6C illustrates a semiconductor structure 600c, which can be formed by forming first connection structures 604 and contact structures 608. As shown in FIG. 6C, the first connection structures 604 extend through the first deck 603 along the Z direction. In some implementations, each of the one or more first semiconductor structure 602 in the first deck 603 includes a corresponding contact structure 608. The contact structures 608 can be formed by etching a portion of the stack 603 along the first direction to form contact holes. The contact holes can be connected to each of the first semiconductor structures 602 of the stack 603. The contact holes for each of the first semiconductor structures 602 can be formed through multiple etching process so that each of the first semiconductor structures 602 is coupled to at least one corresponding contact hole. The contact structures 608 can be then formed by depositing a conductive material into the contact holes after the multiple etching process. In some implementations, the contact structures 608 can include an inner conductive filling surrounded by a dielectric outer layer. In some implementations, the one or more first semiconductor structures 602 can be formed on one wafer die, and the first semiconductor structures 602 can be separated by a dicing process.

As shown in FIG. 6D, a semiconductor structure 600d is formed. In some implementations, the semiconductor structure 600d includes a second semiconductor structure 610. In some implementations, the second semiconductor structure 610 can be a non-volatile memory device such as a NAND flash memory device.

FIG. 6E illustrates a semiconductor structure 600e, which can be formed by forming one or more second connection structures 612 in the second semiconductor structure 610. As shown in FIG. 6E, the second connection structures 612 extend through the second semiconductor structure 610 along the Z direction.

FIG. 6F illustrates a semiconductor structure 600f, which can be formed by forming a first bonding layer 614 on one side of the second semiconductor structure 610. As shown in FIG. 6F, the first bonding layer 614 includes conductive bonding contacts 613 and a dielectric material 615 isolating the conductive bonding contacts 613.

FIG. 6G illustrates a semiconductor structure 600g, which can be formed by stacking one or more second semiconductors structures 610 on top of each other to form a second deck 605. As show in FIG. 6G, two adjacent second semiconductor structures 610 are bonded together by a corresponding first bonding layer 614 along the Z direction. In some implementations, the second connection structures 612 in each of the second semiconductor structures 610 are aligned with each other. In some implementations, the one or more second semiconductor structures 610 can be formed on one wafer die, and the second semiconductor structures 610 can be separated by a dicing process. The semiconductor structure 600g also includes a second bonding layer 616, which is formed on a bottom of the second deck 605.

FIG. 6H illustrates a semiconductor structure 600h, which can be formed by bonding the first deck 603 and the second deck 605 along the first direction through the second bonding layer 616. As shown in FIG. 6H, the first connection structures 604 of the first deck 603 are aligned and coupled with the second connection structures 612 of the second deck 605 along the Z direction.

FIG. 6I illustrates a semiconductor structure 600i, which can be formed by bonding a logic device 618 on the first deck 603. In some implementations, the first deck 603 is between the logic device 618 and the second deck 605 along the Z direction.

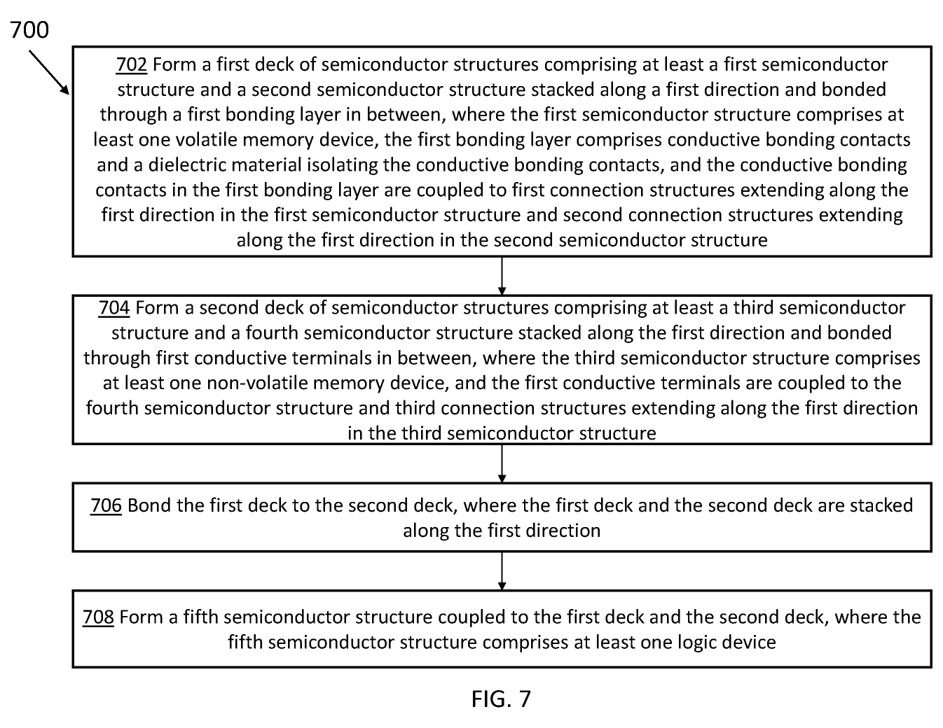

FIG. 7 illustrates a flow chart of an example process 700. The process 700 can be performed to form a semiconductor device (e.g., the semiconductor device 100a illustrated by FIG. 1A). The process 700 can be described in view of FIGS. 5A – 5J. The process 700 can include one or more steps of the fabrication process of forming the semiconductor structures in FIGS. 5A – 5J. It is understood that the operations shown in process 700 are not exhaustive and that other operations can be performed as well before, after, or between any of the illustrated operations. Further, some of the operations may be performed simultaneously, or in a different order than shown in FIG. 7.

At operation 702, a first deck (e.g., the first deck 102 of FIG. 1A) of semiconductor structures comprising at least a first semiconductor structure (e.g., the first volatile memory device 106a of FIG. 1A) and a second semiconductor structure (e.g., the second volatile memory device 106b of FIG. 1A) stacked along a first direction (e.g., the Z direction) and bonded through a first bonding layer (e.g., the first bonding layer 108a of FIG. 1A) in between is formed, where the first semiconductor structure comprises at least one volatile memory device, the first bonding layer comprises conductive bonding contacts (e.g., the conductive bonding contacts 110 of FIG. 1A) and a dielectric material (e.g., the dielectric material 111 of FIG. 1A) isolating the conductive bonding contacts, and the conductive bonding contacts in the first bonding layer are coupled to first connection structures (e.g., the connection structures 112a of FIG. 1A) extending along the first direction in the first semiconductor structure and second connection structures (e.g., the connection structures 112b of FIG. 1A) extending along the first direction in the second semiconductor structure.

At operation 704, a second deck (e.g., the second deck 104 of FIG. 1A) of semiconductor structures comprising at least a third semiconductor structure (e.g., the first non-volatile memory device 114a of FIG. 1A) and a fourth semiconductor structure (e.g., the second non-volatile memory device 114b of FIG. 1A) stacked along the first direction and bonded through first conductive bumps (e.g., the conductive bumps 116a of FIG. 1A) in between is formed, where the third semiconductor structure comprises at least one non-volatile memory device, and the first conductive bumps are coupled to the fourth semiconductor structure and third connection structures (e.g., the connection structures 113a of FIG. 1A) extending along the first direction in the third semiconductor structure.

At operation 706, the first deck is bonded to the second deck, where the first deck and the second deck are stacked along the first direction.

At operation 708, a fifth semiconductor structure (e.g., the logic device 118 of FIG. 1A) coupled to the first deck and the second deck is formed, where the fifth semiconductor structure comprises at least one logic device.

In some implementations, forming the first deck includes forming the first semiconductor structure; forming the first connection structures in the first semiconductor structure; forming the second semiconductor structure; forming the second connection structures in the second semiconductor structure; forming a first sub-bonding layer (e.g., the first sub-bonding layer 506 of FIG. 5C) on top of the first semiconductor structure, where the first sub-bonding layer includes conductive bonding contacts and a dielectric material isolating the conductive bonding contacts; forming a second sub-bonding layer on bottom of the second semiconductor structure, where the second sub-bonding layer includes conductive bonding contacts and a dielectric material isolating the conductive bonding contacts, and the conductive bonding contacts in the first sub-bonding layer are configured to align with the conductive bonding contacts in the second sub-bonding layer along the first direction; and bonding the first semiconductor structure to the second semiconductor structure by bonding the conductive bonding contacts in the first sub-bonding layer to the conductive bonding contacts in the second sub-bonding layer and the dielectric material in the first sub-bonding layer to the dielectric material in the second sub-bonding layer.

In some implementations, forming the second deck includes forming the third semiconductor structure; forming the third connection structures in the third semiconductor structure; forming the fourth semiconductor structure; forming conductive bonding contacts (e.g., the conductive bumps 518 of FIG. 5G) on top of the third semiconductor structure; forming the first conductive bumps on bottom of the fourth semiconductor structure, where the conductive bonding contacts on top of the third semiconductor structure are configured to align with the first conductive bumps on bottom of the fourth semiconductor structure; and bonding the third semiconductor structure to fourth second semiconductor structure by bonding the conductive bonding contacts on top of the third semiconductor structure to the first conductive bumps on bottom of the fourth semiconductor structure.

In some implementations, bonding the first deck to the second deck includes forming conductive bonding contacts on top of the first deck; forming conductive bumps (e.g., conductive bonding contacts 520 of FIG. 5I) on bottom of the second deck, where the conductive bonding contacts on top of the first deck are configured to align with the conductive bumps on bottom of the second deck; and bonding the conductive bonding contacts on top of the first deck to the conductive bumps on bottom of the second deck.

In some implementations, the method further includes bonding the first deck to the fifth semiconductor structure, where the first deck and fifth semiconductor structure are stacked along the first direction; and bonding the fifth semiconductor structure to an interposer (e.g., the interposer 120 of FIG. 1A), where the second deck, the first deck, the fifth semiconductor structure, and the interposer are stacked along the first direction.

In some implementations, the method further includes bonding the first deck to an interposer (e.g., the interposer 120 of FIG. 1E), where the second deck, the first deck, and the interposer are stacked along the first direction; and bonding the fifth semiconductor structure to the interposer, where the fifth semiconductor structure and the interposer are stacked along the first direction, and the first deck and the fifth semiconductor structure are integrated on different positions of the interposer along a second direction perpendicular to the first direction.

FIG. 8 illustrates a flow chart of an example process 800. The process 800 can be performed to form a semiconductor device (e.g., the semiconductor device 800a illustrated by FIG. 8A). The process 800 can be described in view of FIGS. 6A –6I. The process 800 can include one or more steps of the fabrication process of forming the semiconductor structures in FIGS. 6A – 6I. It is understood that the operations shown in process 800 are not exhaustive and that other operations can be performed as well before, after, or between any of the illustrated operations. Further, some of the operations may be performed simultaneously, or in a different order than shown in FIG. 8.

At operation 802, a first deck (e.g., the first deck 202 of FIG. 2A) of semiconductor structures comprising at least a first semiconductor structure (e.g., the first volatile memory device 106a of FIG. 2A) and a second semiconductor structure (e.g., the second volatile memory device 106b of FIG. 2A) stacked along a first direction (e.g., the Z direction) and bonded through a first bonding layer (e.g., the first bonding layer 208a of FIG. 2A) in between is formed, where the first semiconductor structure comprises at least one volatile memory device, and the first bonding layer comprises a dielectric material and excludes a conductive bonding contact, the first deck further comprises first connection structures (e.g., the connection structures 210 of FIG. 2A), a first contact structure (e.g., the first contact structure 211a of FIG. 2A), and a second contact structure (e.g., the second contact structure 211b of FIG. 2A) extending along the first direction, the first connection structures extend through the first bonding layer, the first contact structure extends through the second bonding layer and is coupled to the second semiconductor structure, and the second contact structure extends into and is coupled to the first semiconductor structure.

At operation 804, a second deck (e.g., the second deck 204 of FIG. 2A) of semiconductor structures comprising at least a third semiconductor structure (e.g., the first non-volatile memory device 214a of FIG. 2A) and a fourth semiconductor structure (e.g., the second non-volatile memory device 214b of FIG. 2A) stacked along the first direction and bonded through a second bonding layer (e.g., the second bonding layer 216b of FIG. 2A) in between, where the third semiconductor structure comprises at least one non-volatile memory device is formed, and the second bonding layer comprises conductive bonding contacts (e.g., the conductive bonding contacts 218 of FIG. 2A) and a dielectric material (e.g., the dielectric material 220 of FIG. 2A) isolating the conductive bonding contacts, and the conductive bonding contacts in the second bonding layer are coupled to the fourth semiconductor structure and second connection structures (e.g., the second connection structures 212 of FIG. 2A) in the third semiconductor structure.

At operation 806, the first deck is bonded to the second deck, where the first deck and the second deck are stacked along the first direction, and the second connection structures in the third semiconductor structure are coupled to the first connection structures in the first deck.

At operation 808, a fifth semiconductor structure (e.g., the logic device 224 of FIG. 2A) coupled to the first deck and the second deck is formed, where the fifth semiconductor structure comprises at least one logic device.

In some implementations, forming the first deck includes forming the first semiconductor structure; forming the second semiconductor structure; forming a first dielectric layer on top of the first semiconductor structure; forming a second dielectric layer on bottom of the second semiconductor structure; and bonding the first semiconductor structure to the second semiconductor structure by bonding the first dielectric layer to the second dielectric layer, where the first bonding layer includes the first dielectric layer and the second dielectric layer.

In some implementations, forming the first deck further includes forming the first connection structures extending through the first semiconductor structure, the first bonding layer, and the second semiconductor structure; forming the first contact structure extending through the first semiconductor structure and the first bonding layer and into the second semiconductor structure; forming the second contact structure extending into the first semiconductor structure without extending through the first bonding layer; and forming an interconnect layer on top of the first deck, where the interconnect layer is coupled to the first connection structures.

In some implementations, forming the second deck includes forming the third semiconductor structure; forming the second connection structures in the third semiconductor structure; forming the fourth semiconductor structure; forming a first sub-bonding layer on top of the third semiconductor structure, where the first sub-bonding layer includes conductive bonding contacts and a dielectric material isolating the conductive bonding contacts; forming a second sub-bonding layer on bottom of the fourth semiconductor structure, where the second sub-bonding layer includes conductive bonding contacts and a dielectric material isolating the conductive bonding contacts, and the conductive bonding contacts in the first sub-bonding layer are configured to align with the conductive bonding contacts in the second sub-bonding layer along the first direction; and bonding the third semiconductor structure to the fourth semiconductor structure by bonding the conductive bonding contacts in the first sub-bonding layer to the conductive bonding contacts in the second sub-bonding layer and the dielectric material in the first sub-bonding layer to the dielectric material in the second sub-bonding layer.

In some implementations, bonding the first deck to the second deck includes forming a third sub-bonding layer on top of the first deck, where the third sub-bonding layer includes conductive bonding contacts and a dielectric material isolating the conductive bonding contacts, and the conductive bonding contacts in the third sub-bonding layer are coupled to an interconnect layer of the first deck; forming a fourth sub-bonding layer on bottom of the second deck, where the fourth sub-bonding layer includes conductive bonding contacts and a dielectric material isolating the conductive bonding contacts, the conductive bonding contacts in the fourth sub-bonding layer are configured to align with the conductive bonding contacts in the third sub-bonding layer along the first direction, and the conductive bonding contacts in the fourth sub-bonding layer are coupled to the second connection structures in the third semiconductor structure; and bonding the first deck to the second deck by bonding the conductive bonding contacts in the third sub-bonding layer to the conductive bonding contacts in the fourth sub-bonding layer and the dielectric material in the third sub-bonding layer to the dielectric material in the fourth sub-bonding layer.

In some implementations, the method further includes bonding the first deck to the fifth semiconductor structure, where the first deck and fifth semiconductor structure are stacked along the first direction; and bonding the fifth semiconductor structure to an interposer (e.g., the interposer 226 of FIG. 2A), where the second deck, the first deck, the fifth semiconductor structure, and the interposer are stacked along the first direction.

In some implementations, the method further includes bonding the first deck to an interposer (e.g., the interposer 226 of FIG. 2E), where the second deck, the first deck, and the interposer are stacked along the first direction; and bonding the fifth semiconductor structure to the interposer, where the fifth semiconductor structure and the interposer are stacked along the first direction, and the first deck and the fifth semiconductor structure are integrated on different positions of the interposer along a second direction perpendicular to the first direction.

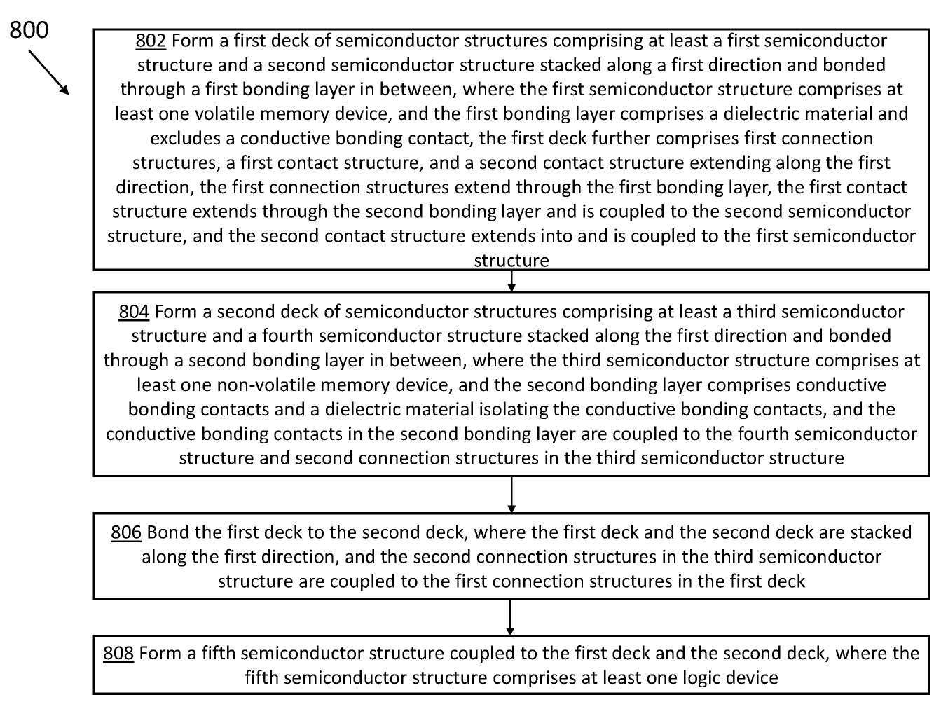

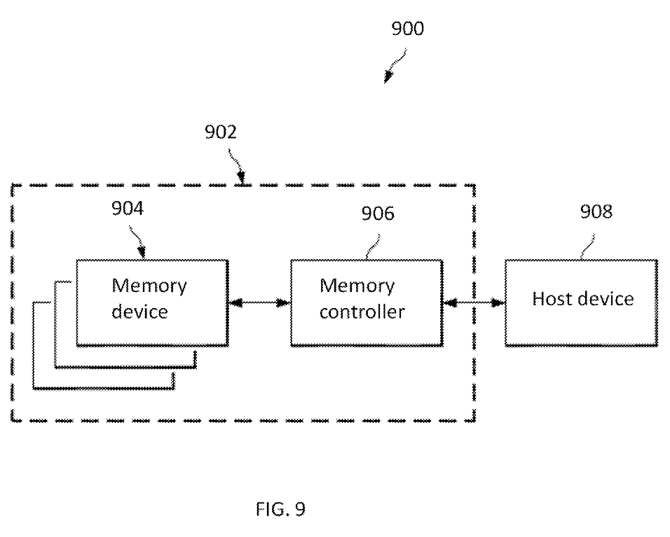

FIG. 9 illustrates a block diagram of a system 900 having one or more semiconductor devices (e.g., memory devices), according to one or more implementations of the present disclosure. The system 900 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 9, the system 900 can include a host device 908 and a memory system 902 having one or more 3D memory devices 904 and a memory controller 906. Host device 908 can include a processor of an electronic device, such as a central processing unit (CPU), or a system-on-chip (SoC), such as an application processor (AP). Host device 908 can be configured to send or receive data to or from the one or more 3D memory devices 904.

A 3D memory device 904 can be any 3D memory device disclosed herein, such as a 3D memory device depicted in FIGS. 1A – 1F and 2A – 2F. In some implementations, a 3D memory device 904 includes a DRAM memory. Memory controller 906 (a.k.a., a controller circuit) is coupled to 3D memory device 904 and host device 908. Consistent with implementations of the present disclosure, 3D memory device 904 can include a plurality of conductive interconnections through a cover layer that are in contact with conductive pads in a conductive pad layer, and memory controller 906 can be coupled to 3D memory device 904 through at least one of the plurality of conductive interconnections. Memory controller 906 is configured to control 3D memory device 904. For example, memory controller 906 may be configured to operate a plurality of channel structures via word lines. Memory controller 906 can manage data stored in 3D memory device 904 and communicate with host device 908.

In some implementations, memory controller 906 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 906 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 906 can be configured to control operations of 3D memory device 904, such as read, erase, and program (or write) operations. Memory controller 906 can also be configured to manage various functions with respect to the data stored or to be stored in 3D memory device 904 including, but not limited to bad-block management, garbage collection, logical-to-physical address conversion, wear leveling, etc. In some implementations, memory controller 906 is further configured to process error correction codes (ECCs) with respect to the data read from or written to 3D memory device 904. Any other suitable functions may be performed by memory controller 906 as well, for example, formatting 3D memory device 904.

Memory controller 906 can communicate with an external device (e.g., host device 908) according to a particular communication protocol. For example, memory controller 906 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 906 and one or more 3D memory devices 904 can be integrated into various types of storage devices, for example, be included in the same package, such as a universal Flash storage (UFS) package or an eMMC package. That is, memory system 902 can be implemented and packaged into different types of end electronic products. In one example as shown in FIG. 9, memory controller 906 and a single 3D memory device 904 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature’s relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+-.10%, .+-.20%, or .+-.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first deck of volatile memory devices comprising at least a first volatile memory device and a second volatile memory device stacked along a first direction and bonded through a first bonding layer in between, wherein the first bonding layer comprises conductive bonding contacts and a dielectric material isolating the conductive bonding contacts, and the conductive bonding contacts in the first bonding layer are coupled to first connection structures extending along the first direction in the first volatile memory device and second connection structures extending along the first direction in the second volatile memory device;
a second deck of non-volatile memory devices stacked on the first deck along the first direction, wherein the second deck comprises at least a first non-volatile memory device and a second non-volatile memory device stacked along the first direction and bonded through first conductive bumps in between, and the first conductive bumps are coupled to fourth connection structures in the second non-volatile memory device and third connection structures in the first non-volatile memory device; and
a logic device coupled to the first deck and the second deck.

2. The semiconductor device of claim 1, wherein the first volatile memory device comprises a dynamic random access memory (DRAM) device, and the first non-volatile memory device comprises a NAND flash memory device.

3. The semiconductor device of claim 2, wherein the DRAM device comprises a first semiconductor structure comprising an array of DRAM cells and a second semiconductor structure comprising a peripheral circuit configured to control the array of DRAM cells, and the first semiconductor structure and the second semiconductor structure are stacked along the first direction.

4. The semiconductor device of claim 3, wherein the first semiconductor structure and the second semiconductor structure are bonded through a second bonding layer in between comprising conductive bonding contacts and a dielectric material isolating the conductive bonding contacts.

5. The semiconductor device of claim 4, wherein the first semiconductor structure and the second semiconductor structure are bonded through a third bonding layer in between comprising conductive bonding contacts and a dielectric material isolating the conductive bonding contacts.

6. The semiconductor device of claim 1, wherein the first deck and the second deck are coupled through second conductive bumps in between, and the second conductive bumps are isolated by an insulation material.

7. The semiconductor device of claim 1, wherein the logic device comprises a control circuit module, and the control circuit module comprises an access frequency judgement unit configured to determine an access frequency of a data unit stored in the first deck or the second deck.

8. The semiconductor device of claim 1, wherein a pitch of the first connection structures in the first volatile memory device is smaller than a pitch of the third connection structures in the first non-volatile memory device.

9. The semiconductor device of claim 1, wherein the semiconductor device has a first device area, a second device area, and a connection area between the first device area and the second device area along a second direction perpendicular to the first direction, and the first connection structures in the first volatile memory device comprise input/output (I/O) connection structures in the connection area and power connection structures in the first device area, the second device area, and the connection area, the I/O connection structures are configured to provide data path signals to the first volatile memory device, and the power connection structures are configured to provide power supplies to the first volatile memory device.

10. The semiconductor device of claim 1, wherein the second deck comprises at least 256 input/output (I/O) pins, the second deck comprises four non-volatile memory devices, one of the four non-volatile memory devices comprises eight channels, and one of the eight channels comprises at least six planes and eight I/O pins.

11. The semiconductor device of claim 1, wherein at least one volatile memory device of the first deck of volatile memory devices is configured to store hot data with a relatively higher access frequency, and at least one non-volatile memory device of the second deck of non-volatile memory devices is configured to store warm or cold data with a relatively lower access frequency.

12. A method, comprising:
forming a first deck of semiconductor structures comprising at least a first semiconductor structure and a second semiconductor structure stacked along a first direction and bonded through a first bonding layer in between, wherein the first semiconductor structure comprises at least one volatile memory device, the first bonding layer comprises conductive bonding contacts and a dielectric material isolating the conductive bonding contacts, and the conductive bonding contacts in the first bonding layer are coupled to first connection structures extending along the first direction in the first semiconductor structure and second connection structures extending along the first direction in the second semiconductor structure;
forming a second deck of semiconductor structures comprising at least a third semiconductor structure and a fourth semiconductor structure stacked along the first direction and bonded through first conductive bumps in between, wherein the third semiconductor structure comprises at least one non-volatile memory device, and the first conductive bumps are coupled to the fourth semiconductor structure and third connection structures extending along the first direction in the third semiconductor structure;
bonding the first deck to the second deck, wherein the first deck and the second deck are stacked along the first direction; and
forming a fifth semiconductor structure coupled to the first deck and the second deck, wherein the fifth semiconductor structure comprises at least one logic device.

13. The method of claim 12, wherein forming the first deck comprises:
forming the first semiconductor structure;
forming the first connection structures in the first semiconductor structure;
forming the second semiconductor structure;
forming the second connection structures in the second semiconductor structure;
forming a first sub-bonding layer on top of the first semiconductor structure, wherein the first sub-bonding layer comprises conductive bonding contacts and a dielectric material isolating the conductive bonding contacts;
forming a second sub-bonding layer on bottom of the second semiconductor structure, wherein the second sub-bonding layer comprises conductive bonding contacts and a dielectric material isolating the conductive bonding contacts, and the conductive bonding contacts in the first sub-bonding layer are configured to align with the conductive bonding contacts in the second sub-bonding layer along the first direction; and
bonding the first semiconductor structure to the second semiconductor structure by bonding the conductive bonding contacts in the first sub-bonding layer to the conductive bonding contacts in the second sub-bonding layer and the dielectric material in the first sub-bonding layer to the dielectric material in the second sub-bonding layer.

14. The method of claim 12, wherein forming the second deck comprises:
forming the third semiconductor structure;
forming the third connection structures in the third semiconductor structure;
forming the fourth semiconductor structure;
forming conductive bonding contacts on top of the third semiconductor structure;
forming the first conductive bumps on bottom of the fourth semiconductor structure, wherein the conductive bonding contacts on top of the third semiconductor structure are configured to align with the first conductive bumps on bottom of the fourth semiconductor structure; and
bonding the third semiconductor structure to the fourth semiconductor structure by bonding the conductive bonding contacts on top of the third semiconductor structure to the first conductive bumps on bottom of the fourth semiconductor structure.

15. The method of claim 12, wherein bonding the first deck to the second deck comprises:
forming conductive bonding contacts on top of the first deck;
forming conductive bumps on bottom of the second deck, wherein the conductive bonding contacts on top of the first deck are configured to align with the conductive bumps on bottom of the second deck; and
bonding the conductive bonding contacts on top of the first deck to the conductive bumps on bottom of the second deck.

16. The method of claim 12, further comprising:
bonding the first deck to the fifth semiconductor structure, wherein the first deck and the fifth semiconductor structure are stacked along the first direction; and
bonding the fifth semiconductor structure to an interposer, wherein the second deck, the first deck, the fifth semiconductor structure, and the interposer are stacked along the first direction.

17. A semiconductor device, comprising:
a first deck of volatile memory devices comprising at least a first volatile memory device and a second volatile memory device stacked along a first direction and bonded through a first bonding layer in between, wherein the first bonding layer comprises a dielectric material and excludes a conductive bonding contact, the first deck further comprises first connection structures, a first contact structure, and a second contact structure extending along the first direction, the first connection structures extend through the first bonding layer, the first contact structure extends through the first bonding layer and is coupled to the second volatile memory device, and the second contact structure extends into and is coupled to the first volatile memory device without extending through the first bonding layer;
a second deck of non-volatile memory devices stacked on the first deck along the first direction, wherein the second deck comprises at least a first non-volatile memory device and a second non-volatile memory device stacked along the first direction and bonded through a second bonding layer in between, the second bonding layer comprises conductive bonding contacts and a dielectric material isolating the conductive bonding contacts, the conductive bonding contacts in the second bonding layer are coupled to the second non-volatile memory device and second connection structures extending along the first direction in the first non-volatile memory device, and the second connection structures in the first non-volatile memory device are coupled to the first connection structures in the first deck; and
a logic device coupled to the first deck and the second deck.

18. The semiconductor device of claim 17, wherein the first volatile memory device comprises a dynamic random access memory (DRAM) device, and the first non-volatile memory device comprises a NAND flash memory device.

19. The semiconductor device of claim 18, wherein the DRAM device comprises a first semiconductor structure comprising an array of DRAM cells and a second semiconductor structure comprising a peripheral circuit configured to control the array of DRAM cells, and the first semiconductor structure and the second semiconductor structure are stacked along the first direction.

20. The semiconductor device of claim 17, wherein a pitch of the first connection structures, the first contact structure, and the second contact structure is equal to or smaller than a pitch of the second connection structures in the first non-volatile memory device.
